(19) United States
(12) Patent Application Publication
(10) Pub. No.: US 2024/0192418 A1
(43) Pub. Date: Jun. 13, 2024

(54) POLARIZER PROTECTIVE FILM

(71) Applicant: OSAKA GAS CHEMICALS CO., LTD., Osaka (JP)

(72) Inventors: Shogo SUGA, Osaka (JP); Yoshiya OTA, Osaka (JP); Yasuhiro SUDA, Osaka (JP)

(21) Appl. No.: 18/280,939

(22) PCT Filed: Mar. 15, 2022
(86) PCT No.: PCT/JP2022/011598

§ 371 Date: Sep. 7, 2023

(30) Foreign Application Priority Data
Mar. 16, 2021 (JP) 2021-042963

(51) Int. Cl. G02B 5/30; G02B 1/111; G02B 1/14; G06F 1/16; G06F 3/044

(52) U.S. Cl. CPC G02B 5/3083; G02B 1/111; G02B 1/14; G06F 1/1616; G06F 3/0446

(57) ABSTRACT

Provided is a polarizer protective film which is a multilayer film having a polyester-based resin layer comprising a fluorene-based polyester resin, and an acrylic resin layer comprising an acrylic resin.

### TECHNICAL FIELD

The present invention relates to a polarizer protective film, a polarizing plate comprising the polarizer protective film, and an image display apparatus comprising at least one polarizing plate.

### BACKGROUND ART

Heretofore, polyvinyl alcohol (PVA)-based resin films stained with iodine or a dichroic dye, etc. and oriented by drawing or the like have been used as polarizers for polarizing plates for use in image display apparatuses. Such a polarizer is susceptible to ultraviolet ray, moisture, or heat, and its polarization performance is deteriorated due to decomposition, dimensional change, or the like. In order to prevent this event, a transparent protective film laminated to one side or both sides of the polarizer through an adhesive is used as a polarizing plate.

Triacetylcellulose (TAC) is generally used as this polarizer protective film for reasons such as transparency, optical isotropy, and an excellent adhesive property to PVA. Meanwhile, liquid crystal panels are transported in simple packages in an increased number of cases for cost reduction associated with recent price decrease of liquid crystal televisions, and thus require durability capable of resisting temperature change or humidity change during transport. Particularly, there is an increasing need for, particularly, low moisture-permeable polarizing plates. Hence, materials have been demanded instead of TAC films which have a high degree of moisture permeation. Films of various modified acrylic resins (Patent Literatures 1 and 2), a polyethylene terephthalate resin having a specific range of a retardation value (Patent Literature 3), and the like have been developed and put into practical use.

Also, thin polarizing plates have been demanded in association with thin liquid crystal displays, and the thinning of TAC films for use in the polarizing plates is underway. However, the thinning of TAC films disadvantageously deteriorates mechanical strength or moisture permeability. In this respect, materials are also demanded instead of TAC films.

Acrylic resin films have a degree of moisture permeation as low as approximately 1/10 of that of TAC films and however, are hard and fragile. Therefore, a problem of the acrylic resin films is that a crack occurs from an end part at the time of film cutting or at the time of lamination and take-up, decreasing production yields of polarizing plates. Since smaller film thicknesses of films markedly decrease yields, the film thicknesses cannot be decreased beyond a certain degree. At present, a demand for thin films cannot be sufficiently met.

In order to prevent the ultraviolet deterioration of iodine in a polarizer, an ultraviolet absorber is usually contained in a protective film. However, its content is restricted depending on the solubility of the ultraviolet absorber in a resin. Hence, the ultraviolet absorber necessary for the protection of iodine is more difficult to contain with decrease in film thickness. Thus, a large content thereof in a thin acrylic resin film causes problems such as bleed-out.

General-purpose polyethylene terephthalate resins have a much lower degree of moisture permeation than that of modified acrylic resins and are also excellent in mechanical strength, and however, cannot be used as polarizer protective films due to retardation resulting in the occurrence of iridescent unevenness. However, the polyethylene terephthalate resin having a specific range of a retardation value exhibits a spectrum similar to the emission spectrum of a backlight by controlling retardation to a high value and thereby canceling interference color, and can thereby be used as a polarizer protective film because the iridescent unevenness of a polarizing plate is solved. This polyethylene terephthalate resin has a retardation value of several times to 10 or more times the retardation value of a general-purpose polyethylene terephthalate resin. However, since the retardation is parallel to the thickness of a film, a film thickness beyond a certain degree is necessary for securing such a high retardation value. At present, it is difficult to render a film as thin as necessary.

### CITATION LIST

### Patent Literature

Patent Literature 1: WO2006/112207
Patent Literature 2: WO2005/054311
Patent Literature 3: Japanese Patent No. 4962661

### SUMMARY OF INVENTION

### Technical Problem

Accordingly, it is possible to use, as a polarizer protective film, a fluorene-based polyester resin film that is excellent in mechanical characteristics such as toughness, has a low in-plane phase difference, and is useful as an optical film. As a result of conducting studies, however, the present inventors have found that the fluorene-based polyester resin film has relatively large phase difference Rth in a thickness direction and requires further reducing Rth for use in a single layer as a polarizer protective film.

In the case of using an acrylic resin or a polyethylene terephthalate resin as a protective film for PVA polarizers as described above, an aqueous adhesive, for example, a polyvinyl alcohol-based adhesive, for use in a TAC film for adhesion to a PVA polarizer cannot be used due to a slow drying rate of water because the protective film has low moisture permeability. Hence, an organic adhesive, particularly, an ultraviolet-curable adhesive, is used. However, the ultraviolet-curable adhesive needs to be customized depending on user's use conditions such as the absence of a solvent, a viscosity, an integral quantity of light, adhesive strength, and a film thickness. Thus, it is generally difficult to directly apply a commercially available product thereto.

The present invention has been made to solve the problems described above. An object of the present invention is to provide (1) a polarizer protective film that has excellent optical characteristics, is also excellent in durability and mechanical strength, can be thinned, is inexpensive, and is excellent in productivity, (2) to provide a polarizing plate comprising such a polarizer protective film and a polarizer formed from a polyvinyl alcohol-based resin, (3) to provide an image display apparatus comprising such a polarizing plate, and (4) to provide an information processing apparatus comprising such an image display apparatus.

### Solution to Problem

The present inventors have conducted diligent studies to attain the object and consequently completed the present invention by finding that a multilayer film comprising a polyester-based resin is effective as a polarizer protective film targeted by the present invention and further, is also effective for a polarizing plate by using an ultraviolet-curable adhesive effective for adhesion to a polarizer.

[1]

A polarizer protective film which is a multilayer film
having a polyester-based resin layer comprising a fluorene-based polyester resin, and acrylic resin layer comprising an acrylic resin, and
being formed by drawing, wherein
a thickness ratio of the polyester-based resin layer to the whole is 1 to 30%,
phase difference Rth(589) in a thickness direction at a wavelength of 589 nm is −50 nm or more and 50 nm or less, and
in-plane phase difference Ro(550) at a wavelength of 550 nm is 0 nm or more and 50 nm or less.
   [2]

The polarizer protective film according to [1], wherein
the fluorene-based polyester resin is a co-polyester resin comprising repeat units represented by the following general formula (1) and the following general formula (3):

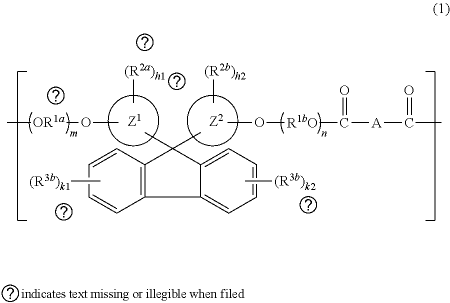

wherein A represents a benzene residue, a naphthaline residue, a cyclohexane residue, a decalin residue, or a fluorene residue represented by the following general formula (2), Z¹ and Z² are the same or different and each represent a phenylene group or a naphthylene group, R^{1a} and R^{1b} are the same or different and each represent a C₂₋₆ alkylene group, m and n are the same or different and each represent an integer of 1 to 5, R^{2a} and R^{2b} are the same or different and each represent an alkyl group, an alkoxy group, an aryl group, a cycloalkyl group, an aralkyl group, a cycloalkyloxy group, an aryloxy group, an alkylthio group, a dialkylamino group, a halogen atom, a nitro group, or a cyano group, h1 and h2 are the same or different and each represent an integer of 0 to 2, R^{3a} and R^{3b} are the same or different and each represent a substituent inert to reaction, and k1 and k2 are the same or different and each represent an integer of 0 to 4:

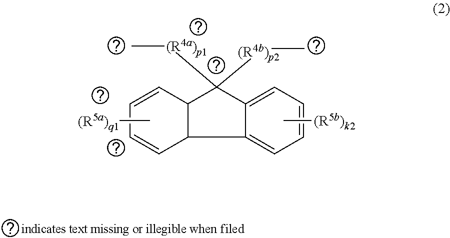

wherein R^{4a} and R^{4b} are the same or different and each represent a C₁₋₈ alkylene group, p1 and p2 are the same or different and each represent an integer of 1 to 5, R^{5a} and R^{5b} are the same or different and each represent a substituent inert to reaction, and q1 and q2 each represent an integer of 0 to 4,

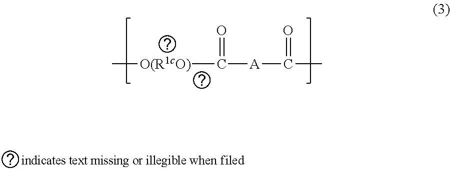

wherein A represents a benzene residue, a naphthaline residue, a cyclohexane residue, a decalin residue, or a fluorene residue represented by the general formula (2), R^{1c} represents a C₂₋₄ alkylene group, and r represents an integer of 1 to 3.
   [3]

The polarizer protective film according to [1] or [2], wherein
the polyester-based resin layer comprising the fluorene-based polyester resin is a polymer alloy comprising the fluorene-based polyester resin and a polycarbonate resin.
   [4]

The polarizer protective film according to any one of [1] to [3], wherein
the acrylic resin comprises a repeat unit represented by any of the following general formulas (4), (5), and (6):

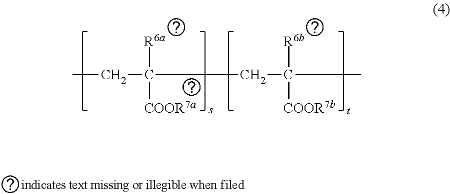

wherein R^{6a} and R^{6b} are the same or different and each represent a hydrogen atom or a C₁₋₈ alkyl group, R^{7a} and R^{7b} are the same or different and each represent a hydrogen atom, a C₁₋₁₈ alkyl group, a C₃₋₁₂ cycloalkyl group, or a substituent containing a C₅₋₁₅ aromatic ring, and s and t each represent a molar fraction with s+t=1,

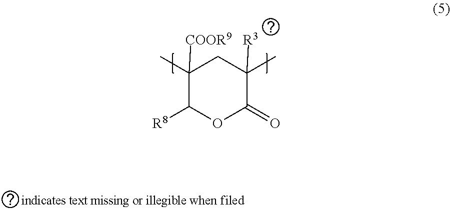

wherein R⁸ represents a hydrogen atom or an organic residue having 1 to 20 carbon atoms, wherein the organic residue optionally contains an oxygen atom, R⁹ represents a hydrogen atom, a C₁₋₁₈ alkyl group, a C₃₋₁₂ cycloalkyl group, or a substituent containing a C₅₋₁₅ aromatic ring, and R¹⁰ represents a hydrogen atom or a C₁₋₈ alkyl group,

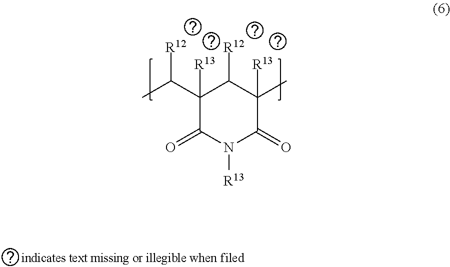

wherein R¹¹ and R¹² are the same or different and each represent a hydrogen atom or a C₁₋₈ alkyl group, and R¹³ represents a hydrogen atom, a C₁₋₁₈ alkyl group, a C₃₋₁₂ cycloalkyl group, or a substituent containing a C₅₋₁₅ aromatic ring.
   [5]

The polarizer protective film according to any one of [1] to [4], wherein
the acrylic resin comprises polymethyl methacrylate.
   [6]

The polarizer protective film according to any one of [1] to [5], wherein
the acrylic resin layer comprising the acrylic resin is a polymer alloy comprising the acrylic resin and a polyester resin or a polycarbonate resin.
   [7]

The polarizer protective film according to [6], wherein
the polyester resin or the polycarbonate resin contained in the acrylic resin layer is a fluorene-based polyester resin or a fluorene-based polycarbonate resin.
   [8]

The polarizer protective film according to any one of [1] to [7], wherein
the polyester-based resin layer and the acrylic resin layer are configured in contact without a layer intended for adhesion.
   [9]

The polarizer protective film according to any one of [1] to [8], wherein
an outermost layer of the multilayer film is the acrylic resin layer, and the multilayer film has three or more layers.
   [10]

The polarizer protective film according to any one of [1] to [9], wherein
the polyester-based resin layer contains an ultraviolet absorber.
   [11]

The polarizer protective film according to any one of [1] to [10], wherein
the multilayer film has a spectral transmittance of 10% or less at 380 nm and a total light transmittance of 85% or more.
   [12]

The polarizer protective film according to any one of [1] to [11], wherein
the polarizer protective film has a surface treatment layer on the surface.
   [13]

The polarizer protective film according to any one of [1] to [12], wherein
the surface treatment layer has any one or more of hard coat, antiglare, antireflection, low-reflection, antifouling, and anti-fingerprint effects.
   [14]

A polarizing plate wherein
the polarizer protective film according to any one of [1] to [13] and a polarizer formed from a polyvinyl alcohol-based resin are laminated through an ultraviolet-curable adhesive.
   [15]

The polarizing plate according to [14], wherein
the ultraviolet-curable adhesive is a composition containing a reaction product of polyester polyol having a 9,9-bis(aryl) fluorene skeleton, a diisocyanate compound, and a hydroxy group-containing acrylate compound, and a monofunctional acrylate compound.
   [16]

An image display apparatus comprising
the polarizing plate according to [14] or [15].
   [17]

An image display apparatus comprising
the polarizing plate according to [14] or [15] and a touch sensor.
   [18]

The image display apparatus according to [17], wherein
the touch sensor has an on-cell system or an in-cell system.
   [19]

The image display apparatus according to [17] or [18], wherein
the touch sensor is a capacitive touch sensor having at least one conductive film.
   [20]

The image display apparatus according to [19], wherein
a base material of the conductive film is a polyester resin, a cycloolefin resin, a polycarbonate resin, or a polyimide resin.
   [21]

The image display apparatus according to [19] or [20], wherein
the conductive film comprises a plurality of metal thin wires.
   [22]

The image display apparatus according to [21], wherein
the metal thin wires are made of silver, copper, or an alloy comprising at least one of silver and copper.
   [23]

The image display apparatus according to any one of [20] to [22], wherein

the conductive film comprises at least one of indium tin oxide (ITO), antimony-doped tin oxide (ATO), a conductive polymer, and a carbon-based material.

[24]

The image display apparatus according to any one of [16] to [23], wherein
the image display apparatus has a changeable shape.
   [25]

The image display apparatus according to any one of [16] to [24], wherein
the image display apparatus is an in-car image display apparatus.
   [26]

An information processing apparatus comprising
the image display apparatus according to any one of [16] to [25].

### Advantageous Effect of Invention

The present invention can provide a polarizer protective film that has excellent optical characteristics, is also excellent in durability and mechanical strength, can be thinned, is inexpensive, and is excellent in productivity.

### BRIEF DESCRIPTION OF DRAWINGS

FIG. 1 is a cross-sectional view schematically illustrating a polarizer protective film according to one embodiment of the present invention.

FIG. 2A is a cross-sectional view schematically illustrating a polarizing plate according to one embodiment of the present invention.

FIG. 2B is a cross-sectional view schematically illustrating a polarizing plate according to another embodiment of the present invention.

FIG. 3A is a cross-sectional view schematically illustrating an image display apparatus (OLED) according to one embodiment of the present invention.

FIG. 3B is a cross-sectional view schematically illustrating an image display apparatus (LCD) according to one embodiment of the present invention.

FIG. 4 is a cross-sectional view schematically illustrating a rollable display according to one embodiment of the present invention.

FIG. 5 is a perspective view schematically illustrating an information processing apparatus according to one embodiment of the present invention.

FIG. 6 is a perspective view schematically illustrating a foldable smartphone according to one embodiment of the present invention.

FIG. 7 is a perspective view schematically illustrating a rollable smartphone according to one embodiment of the present invention.

### DESCRIPTION OF EMBODIMENTS

Hereinafter, the mode for carrying out the present invention (hereinafter, referred to as the “present embodiment”) will be described in detail. However, the present invention is not limited thereby, and various changes or modifications can be made in the present invention without departing from the spirit of the present invention.

### [Polarizer Protective Film]

The polarizer protective film of the present embodiment is a multilayer film having a polyester-based resin layer comprising a fluorene-based polyester resin, and an acrylic resin layer comprising an acrylic resin. This can impart durability and mechanical strength brought about by the polyester-based resin layer to the polarizer protective film. The polyester-based resin layer has good compatibility with an ultraviolet absorber and therefore, can also newly impart ultraviolet absorption performance thereto. Since the acrylic resin layer has transparency and scratch resistance, a polarizer protective film having higher mechanical strength can be obtained. More specifically, the polarizer protective film of the present embodiment is low moisture-permeable and has heat stability, and can therefore prevent the deterioration of a polarizer by moisture or heat. The polarizer protective film of the present embodiment is unlikely to cause iridescent unevenness, light leakage, and the like because of low retardation. The polyester-based resin layer can suppress bleed-out even if an ultraviolet absorber is contained at a high concentration. Therefore, in such a form, the polarizer protective film can prevent ultraviolet deterioration even when thinned.

Furthermore, the polarizer protective film of the present embodiment is prevented from being fragile and is therefore excellent in handleability for taking up the polarizer protective film into a roll. Moreover, the polarizer protective film of the present embodiment can also be thinned by biaxial drawing. The polarizer protective film of the present embodiment can be produced at a large scale by melt extrusion and biaxial drawing because, for example, a general-purpose polymethyl methacrylate resin is used as the acrylic resin.

Particularly, the polarizer protective film of the present embodiment, by having the polyester-based resin layer, is capable of achieving a polarizer protective film having a thickness equivalent to or smaller than that of a conventional polarizer protective film, while improving characteristics such as durability and mechanical strength.

Examples of the multilayer structure of the polarizer protective film include, but are not particularly limited to: a 2-layer structure consisting of the polyester-based resin layer and the acrylic resin layer; a 3-layer structure where the polyester-based resin layer is positioned as an intermediate layer, and the acrylic resin layer is positioned as an outermost layer; a 3-layer structure where the polyester-based resin layer is positioned as an outermost layer, and the acrylic resin layer is positioned as an intermediate layer; a 3-layer structure where the polyester-based resin layer is positioned as one outermost layer, and the acrylic resin layer is positioned as an intermediate layer and another outermost layer; and a structure of arbitrary four or more layers having the acrylic resin layer and the acrylic resin layer. In the present embodiment, it is preferred that the acrylic resin layer should not be a pressure-sensitive adhesive layer. More specifically, the polarizer protective film is preferably a multilayer film having an acrylic resin layer comprising an acrylic resin, and being formed by drawing.

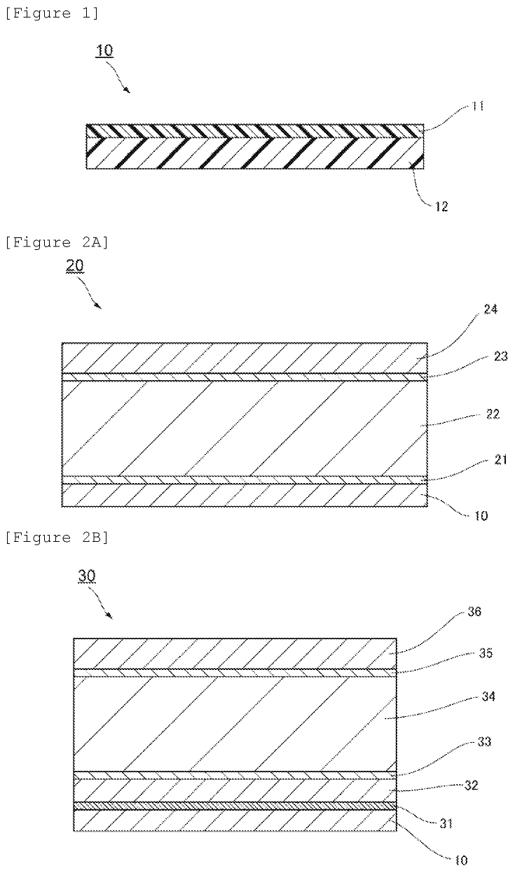

Among others, as shown in FIG. 1, polarizer protective film 10 having a 3-layer structure where polyester-based resin layer 11 is positioned as an intermediate layer, and acrylic resin layer 12 is positioned as an outermost layer, is preferred. This tends to more improve scratch resistance and to reduce a surface reflectance. Such a laminate renders the acrylic resin resistant to cracks. Therefore, the polarizer protective film can be thinner. The polyester-based resin layer is also capable of containing an ultraviolet absorber. Therefore, the polarizer protective film can also be thinned from the viewpoint of an ultraviolet absorption function.

The respective layers of the polarizer protective film may be allowed to adhere to each other via an adhesive layer or may be in contact without a layer intended for adhesion. Among others, it is preferred that the polyester-based resin layer and other layers such as the acrylic resin layer mentioned later should be in contact without a layer intended for adhesion. The polyester-based resin layer can be laminated with the acrylic resin layer with good adhesion and therefore enables the layer intended for adhesion to be omitted. The polarizer protective film can thereby be thinner.

Hereinafter, each layer configuration will be described in detail.

### (Polyester-Based Resin Layer)

The polyester-based resin layer used in the present embodiment comprises a fluorene-based polyester resin given below. The fluorene-based polyester resin preferably has a 9,9-bisarylfluorene skeleton and is preferably, for example, a co-polyester resin comprising repeat units represented by the general formula (1) given below and the general formula (3) given below. Use of such a polyester-based resin tends to more improve durability and mechanical strength. A general polyester resin, when drawn, increases birefringence in the direction of drawing. By contrast, the fluorene-based polyester resin of the present embodiment permits polyester resin design so as to reduce a phase difference as the whole polymer, because the 9,9-bisarylfluorene skeleton contained in a side chain works to increase a phase difference in a direction orthogonal to the direction of drawing.

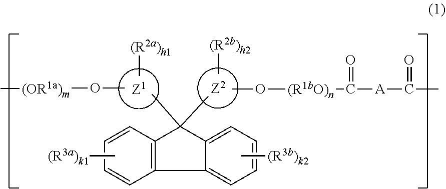

wherein A represents a benzene residue, a naphthaline residue, a cyclohexane residue, a decalin residue, or a fluorene residue represented by the following general formula (2), Z¹ and Z² are the same or different and each represent a phenylene group or a naphthylene group, R^{1a} and R^{1b} are the same or different and each represent a C₂₋₆ alkylene group, m and n are the same or different and each represent an integer of 1 to 5, R^{2a} and R^{2b} are the same or different and each represent an alkyl group, an alkoxy group, an aryl group, a cycloalkyl group, an aralkyl group, a cycloalkyloxy group, an aryloxy group, an alkylthio group, a dialkylamino group, a halogen atom, a nitro group, or a cyano group, h1 and h2 are the same or different and each represent an integer of 0 to 2, R^{3a} and R^{3b} are the same or different and each represent a substituent inert to reaction, and k1 and k2 are the same or different and each represent an integer of 0 to 4:

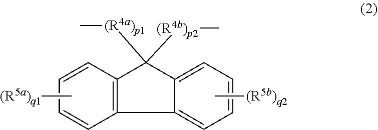

wherein R^{4a} and R^{4b} are the same or different and each represent a C₁₋₈ alkylene group, p1 and p2 are the same or different and each represent an integer of 1 to 5, R^{5a} and R^{5b} each represent a substituent inert to reaction, and q1 and q2 each represent an integer of 0 to 4,

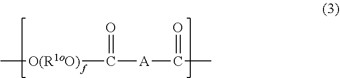

wherein A represents a benzene residue, a naphthaline residue, a cyclohexane residue, a decalin residue, or a fluorene residue represented by the general formula (2), R^{1c} represents a C₂₋₄ alkylene group, and r represents an integer of 1 to 3.

The polyester-based resin layer used in the present embodiment may contain a polyester-based resin different from the fluorene-based polyester resin, and a common polyester-based resin prepared by a common method, for example, a direct polymerization method, a transesterification method, or a ring-opening polymerization method can be used. The polyester-based resin may be, for example, a polyester resin having no aromatic skeleton [e.g., an aliphatic polyester resin (e.g., poly(hydroxy-C₁₋₇ alkane-carboxylic acid) such as polylactic acid and poly(3-hydroxybutyric acid); poly(C₃₋₈ lactone) such as poly(ε-caprolactone); and poly-C₂₋₆ alkylene C₄₋₈ alkanoate such as polybutylene succinate and polybutylene succinate adipate); and an alicyclic polyester resin having at least an alicyclic skeleton (cycloalkane skeleton) (e.g., a polymer of diol having a C₅₋₁₀ cycloalkane ring and C₂₋₆ alkylene-dicarboxylic acid, such as a polymer of cyclohexanedimethanol and adipic acid)]. However, the polyester-based resin is preferably an aromatic polyester resin having at least an aromatic skeleton from the viewpoint of mechanical characteristics, etc. These polyester-based resins can each be used singly, or two or more thereof can be used in combination.

The aromatic polyester resin may be, for example, a polyalkylene arylate-based resin, a polyarylate-based resin [e.g., a polymer of a bisphenol such as bisphenol A and aromatic dicarboxylic acid such as benzenedicarboxylic acid (terephthalic acid, etc.)], or a liquid crystal polyester resin (e.g., a copolymer of p-hydroxybenzoic acid, p, p′-biphenol, and terephthalic acid, a copolymer of p-hydroxybenzoic acid and 2-carboxy-6-hydroxynaphthalene, and a copolymer of p-hydroxybenzoic acid, terephthalic acid, and ethylene glycol). These aromatic polyester resins can each be used singly, or two or more thereof can be used in combination.

The glass transition temperature of the polyester-based resin of the present embodiment is preferably 90 to 160° C., more preferably 105 to 145° C., further preferably 120 to 130° C. When the glass transition temperature is 90° C. or higher, the heat resistance of the polyester-based resin tends to be more improved. When the glass transition temperature is 160° C. or lower, the drawability of the polyester-based resin tends to be more improved. The glass transition temperature can be measured by a method described in Examples mentioned later.

The weight-average molecular weight of the polyester-based resin of the present embodiment is preferably 15000 to 100000, more preferably 25000 to 75000, further preferably 35000 to 50000. When the weight-average molecular weight falls within the range described above, durability and mechanical characteristics tend to be more improved and drawability tends to be more improved. In the present embodiment, the weight-average molecular weight can be measured by gel permeation chromatography (GPC) based on polystyrene. More specifically, the weight-average molecular weight can be measured by, for example, a method described in Examples mentioned later.

Hereinafter, a diol component (A) and a dicarboxylic acid component (B) constituting the fluorene-based polyester resin will be described in detail. Z¹ and Z², R^{1a} to R^{5a} and R^{1b} to R^{5b}, m, n, h1, h2, k1, k2, q1, and q2 in the general formulas (1) to (3) correspond to Z¹ and Z², R^{1a} to R^{5a} and R^{1b} to R^{5b}, m, n, h1, h2, k1, k2, q1, and q2, respectively, in the diol component (A) and the dicarboxylic acid component (B) mentioned later. Examples of Z¹ and Z², R^{1a} to R^{5a} and R^{1b} to R^{5b}, m, n, h1, h2, k1, k2, q1, and q2 in the diol component (A) and the dicarboxylic acid component (B) can be regarded as examples of Z¹ and Z², R^{1a} to Ra and R^{1b} to R^{5b}, m, n, h1, h2, k1, k2, q1, and q2 in the general formulas (1) to (3).

### (Diol Component (A))

The diol component constituting the fluorene-based polyester resin is not particularly limited. For example, a fluorenediol component (A1) represented by the general formula (7) given below is preferably used, and another diol component (A2) may be used, if necessary. Hereinafter, each diol component will be described in detail.

### (Fluorenediol Component (A1))

The fluorenediol component (A1) constituting the diol moiety of the general formula (1) can be represented by the following general formula (7):

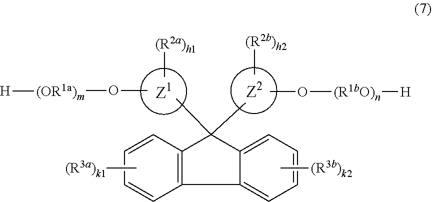

wherein Z¹ and Z² are the same or different and each represent a phenylene group or a naphthylene group, R^{1a} and R^{1b} are the same or different and each represent a C₂₋₆ alkylene group, m and n are the same or different and each represent an integer of 1 to 5, R^{2a} and R^{2b} are the same or different and each represent an alkyl group, an alkoxy group, an aryl group, a cycloalkyl group, an aralkyl group, a nitro group, or a cyano group, h1 and h2 are the same or different and each represent an integer of 0 to 2, R^{3a} and R^{3b} are the same or different and each represent a substituent inert to reaction, and k1 and k2 are the same or different and each represent an integer of 0 to 4.

In the general formula (7), examples of the C₂₋₆ alkylene group represented by the groups R^{1a} and R^{1b} include linear or branched C₂₋₆ alkylene groups such as an ethylene group, a propylene group (1,2-propanediyl group), a trimethylene group, a 1,2-butanediyl group, and a tetramethylene group, preferably C₂₋₄ alkylene groups, further preferably C₂₋₃ alkylene groups. The groups R^{1a} and R^{1b} may be different from each other and may usually be the same.

Each of the numbers (numbers of moles of addition) m and n of oxyalkylene groups (OR^{1a} and OR^{1b}) can be 1 or larger and may be, for example, 1 to 12 (e.g., 1 to 8), preferably 1 to 5 (e.g., 1 to 4), further preferably 1 to 3 (e.g., 1 or 2), particularly, 1. The numbers m and n of substitutions may be the same as or different from each other. When each of m and n is 2 or larger, the repeat units of the alkylene groups represented by the groups R^{1a} and R^{1b} may form different types of alkylene groups and may usually form the same alkylene group.

Examples of the substituents R^{2a} and R^{2b} can include, but are not particularly limited to: hydrocarbon groups such as alkyl groups (e.g., C₁₋₆ alkyl groups such as a methyl group, an ethyl group, a propyl group, an isopropyl group, a butyl group, and a t-butyl group), cycloalkyl groups (e.g., C₅₋₈ cycloalkyl groups such as a cyclohexyl group), aryl groups (e.g., C₆₋₁₀ aryl groups such as a phenyl group, a tolyl group, a xylyl group, and a naphthyl group), and aralkyl groups (e.g., C₆₋₁₀ aryl-C₁₋₄ alkyl groups such as a benzyl group and a phenethyl group); alkoxy groups (e.g., C₁₋₆ alkoxy groups such as a methoxy group and an ethoxy group), cycloalkyloxy groups (e.g., C₅₋₈ cycloalkyloxy groups such as a cyclohexyloxy group), aryloxy groups (e.g., C₆₋₁₀ aryloxy groups such as a phenoxy group), and aralkyloxy groups (e.g., C₆₋₁₀ aryl-C₁₋₄ alkyloxy groups such as a benzyloxy group); alkylthio groups (e.g., C₁₋₈ alkylthio groups such as a methylthio group); acyl groups (e.g., C₁₋₆ alkyl-carbonyl groups such as an acetyl group); halogen atoms (e.g., a fluorine atom, a chlorine atom, a bromine atom, and an iodine atom); a nitro group; a cyano group; dialkylamino groups (e.g., di-C₁₋₄ alkyl-amino groups such as a dimethylamino group); and dialkylcarbonylamino groups (e.g., di-C₁₋₄ alkyl-carbonylamino groups such as a diacetylamino group).

Preferred examples of the group R^{2a} and R^{2b} include alkyl groups (C₁₋₆ alkyl groups, preferably C₁₋₄ alkyl groups, particularly, a methyl group), alkoxy groups (C₁₋₄ alkoxy groups, etc.), cycloalkyl groups (C₅₋₈ cycloalkyl groups), and aryl groups (C₆₋₁₂ aryl groups such as a phenyl group).

The numbers h1 and h2 of substitutions may each be, for example, 0 to 4 (e.g., 0 to 3) and may each be preferably 0 to 2 (e.g., 0 or 1). The numbers h1 and h2 of substitutions may be the same as or different from each other.

In the general formula (7), examples of the groups R^{3a} and R^{3b} include, but are not particularly limited to, nonreactive substituents such as a cyano group, halogen atoms (a fluorine atom, a chlorine atom, a bromine atom, etc.), and hydrocarbon groups [e.g., alkyl groups, aryl groups, and (C₆₋₁₀ aryl groups such as a phenyl group)]. Each of these groups may be a halogen atom, a cyano group, or an alkyl group (particularly, an alkyl group). Examples of the alkyl group can include C₁₋₁₂ alkyl groups (e.g., C₁₋₈ alkyl groups, particularly, C₁₋₄ alkyl groups such as a methyl group) such as a methyl group, an ethyl group, a propyl group, an isopropyl group, a butyl group, and a t-butyl group. The types of the groups R^{3a} and R^{3b} may be the same as or different from each other. The substitution positions of the groups R^{3a} and R^{3b} may be, for example, the 2-position, 7-position, or the 2- and 7-positions of fluorene.

Each of the numbers k1 and k2 of substitutions may be on the order of 0 to 4 (e.g., 0 to 2) and is preferably 0 or 1, particularly, 0. The numbers k1 and k2 of substitutions may be the same as or different from each other. When each of k1 and k2 is a plurality (2 or larger), the types of the substituents R^{3a} or the substituents R^{3b} added to each benzene ring of fluorene may be the same as or different from each other.

In the present embodiment, the phrase “inert to reaction” means being inert to polymerization reaction for the polyester-based resin.

Representative examples of the fluorenediol component (A1) include 9,9-bis(hydroxy (poly)alkoxyphenyl) fluorenes and 9,9-bis(hydroxy (poly)alkoxynaphthyl) fluorenes.

Examples of the 9,9-bis(hydroxy (poly)alkoxyphenyl) fluorenes include, but are not particularly limited to: (i) 9,9-bis(hydroxy-C₂₋₄ alkoxyphenyl) fluorene such as 9,9-bis [4-(2-hydroxyethoxy)phenyl]fluorene and 9,9-bis [4-(2-hydroxypropoxy)phenyl]fluorene; (ii) 9,9-bis(hydroxy-C₂₋₄ alkoxy-mono- or di-C₁₋₄ alkylphenyl) fluorene such as 9,9-bis [4-(2-hydroxyethoxy)-3-methylphenyl]fluorene, 9,9-bis(4-(2-hydroxyethoxy)-3-isopropylphenyl) fluorene, 9,9-bis(4-(2-hydroxyethoxy)-3-isobutylphenyl) fluorene, 9,9-bis(4-(2-hydroxyethoxy)-3-t-butylphenyl) fluorene, 9,9-bis [4-(2-hydroxyethoxy)-3,5-dimethylphenyl]fluorene, and 9,9-bis(4-(2-hydroxyethoxy)-3-t-butyl-5-methylphenyl) fluorene; (iii) 9,9-bis(hydroxy-C₂₋₄ alkoxy-C₅₋₁₀ cycloalkylphenyl) fluorene such as 9,9-bis(4-(2-hydroxyethoxy)-3-cyclohexylphenyl) fluorene; (iv) 9,9-bis(hydroxy-C₂₋₄ alkoxy-C₆₋₁₀ arylphenyl) fluorene such as 9,9-bis [4-(2-hydroxyethoxy)-3-phenylphenyl]fluorene and 9,9-bis [4-(2-hydroxypropoxy)-3-phenylphenyl]fluorene; and compounds in which m and n in the compounds (ii) to (iv) are 2 to 5, for example, 9,9-bis(hydroxy-C₂₋₄ alkoxy-C₂₋₄ alkoxyphenyl) fluorene, 9,9-bis(hydroxy-C₂₋₄ alkoxy-C₂₋₄ alkoxy-mono- or di-C₁₋₄ alkylphenyl) fluorene, and 9,9-bis(hydroxy-C₂₋₄ alkoxy-C₂₋₄ alkoxy-C₆₋₁₀ arylphenyl) fluorene.

Examples of the 9,9-bis(hydroxy (poly)alkoxynaphthyl) fluorenes include: (v) 9,9-bis(hydroxyalkoxynaphthyl) fluorene [e.g., 9,9-bis(hydroxy-C₂₋₄ alkoxynaphthyl) fluorene such as 9,9-bis [6-(2-hydroxyethoxy)-2-naphthyl]fluorene, 9,9-bis [5-(2-hydroxyethoxy)-1-naphthyl]fluorene, and 9,9-bis [6-(2-hydroxypropoxy)-2-naphthyl]fluorene]; and compounds in which m and n in the compounds (v) are 2 to 5, for example, 9,9-bis(hydroxy-C₂₋₄ alkoxy-C₂₋₄ alkoxynaphthyl) fluorene. These fluorenediol component (A1) can each be used singly, or two or more thereof can be used in combination.

In one aspect, the ratio of the diol component (A1) used, though depending on the type or ratio of the dicarboxylic acid component used, is preferably 50 to 99% by mol, more preferably 65 to 95% by mol, further preferably 75 to 90% by mol, based on all diol components (A). When the ratio of the diol component (A1) is 50% by mol or more, durability, mechanical strength, and a glass transition temperature tend to be more improved. When the ratio of the diol component (A1) is 99% by mol or less, a phase difference in a thickness direction or the like tends to be more decreased.

### (Another Diol Component (A2))

The diol component (A) can comprise at least the fluorenediol component (A1), and the fluorenediol component (A1) and another diol component (A2) may be contained to form a co-polyester resin. Examples of another diol component (A2) constituting the diol moiety of the general formula (3) include, but are not particularly limited to, at least one member selected from aliphatic diol, alicyclic diol, and aromatic diol.

Examples of the aliphatic diol can include, but are not particularly limited to, linear or branched alkanediol (C₂₋₁₀ alkanediol such as ethylene glycol, 1,2-propanediol, 1,3-propanediol, 1,2-butanediol, 1,3-butanediol, 1,4-butanediol, 1,3-pentanediol, 1,4-pentanediol, 1,5-pentanediol, neopentyl glycol, and 1,6-hexanediol, preferably C₂₋₆ alkanediol, further preferably C₂₋₄ alkanediol), and polyalkanediol (e.g., di- or tri-C₂₋₄ alkanediol such as diethylene glycol, dipropylene glycol, and triethylene glycol). These aliphatic diols may each be used alone, or two or more thereof may be combined. The aliphatic diol is preferably alkanediol, for example, C₂₋₄ alkanediol such as ethylene glycol.

Examples of the alicyclic diol include, but are not particularly limited to, cycloalkanediol (e.g., C₅₋₈ cycloalkanediol such as cyclohexanediol), di(hydroxyalkyl)cycloalkane (e.g., di(hydroxy-C₁₋₄ alkyl) C₅₋₈ cycloalkane such as cyclohexanedimethanol), and isosorbide. These alicyclic diols may each be used singly, or two or more thereof may be combined.

Examples of the aromatic diol include dihydroxyarene (hydroquinone, resorcinol, etc.), bisphenols (e.g., bis(hydroxyphenyl) C₁₋₁₀ alkane such as biphenol and bisphenol A), di(hydroxyalkyl) arene (e.g., di(hydroxy-C₁₋₄ alkyl) C₆₋₁₀ arene such as 1,3-benzenedimethanol and 1,4-benzenedimethanol), and alkylene oxide adducts of bisphenols. These aromatic diols may each be used singly, or two or more thereof may be combined.

Another diol component (A2) is preferably aliphatic diol and alicyclic diol, particularly, at least aliphatic diol. Specifically, the diol component (A) preferably comprises a fluorenediol component (A1) represented by the general formula (7), such as 9,9-bis(hydroxy (poly) C₂₋₆ alkoxy-C₆₋₁₂ aryl) fluorene, and aliphatic diol (preferably C₂₋₁₀ alkanediol such as ethylene glycol, particularly, C₂₋₆ alkanediol).

In one aspect, the ratio of another diol component (A2) used, though depending on the type or ratio of the dicarboxylic acid component used, is preferably 3 to 50% by mol, more preferably 5 to 35% by mol, further preferably 10 to 25% by mol, based on the whole diol component (A). By use of another diol component (A2) at the ratio as described above, durability and mechanical strength tend to be more improved.

### (Dicarboxylic Acid Component (B))

The dicarboxylic acid component constituting the fluorene-based polyester resin is not particularly limited. For example, a fluorenedicarboxylic acid component (B1) represented by the general formula (8) given below is preferably used, and another dicarboxylic acid component (B2) may be used, if necessary. Hereinafter, each dicarboxylic acid component will be described in detail.

### (Fluorenedicarboxylic Acid Component (B1))

The fluorenedicarboxylic acid component (B1) which is a monomer capable of constituting the polyester resin used in the present embodiment can be represented by the following general formula (8):

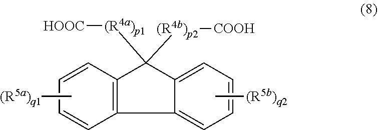

wherein R^{4a} and R^{4b} are the same or different and each represent a C₁₋₈ alkylene group, p1 and p2 are the same or different and each represent an integer of 1 to 5, R^{5a} and R^{5b} are the same or different and each represent a substituent inert to reaction, and q1 and q2 are the same or different and each represent an integer of 0 to 4.

In the general formula (8), examples of the C₁₋₈ alkylene group represented by the groups R^{4a} and R^{4b} can include linear or branched alkylene groups, for example, C₁₋₈ alkylene groups such as a methylene group, an ethylene group, a trimethylene group, a propylene group, a 2-ethylethylene group, and a 2-methylpropane-1,3-diyl group. Among them, the alkylene group is preferably a linear or branched C₁₋₆ alkylene group (e.g., a C₁₋₄ alkylene group such as a methylene group, an ethylene group, a trimethylene group, a propylene group, or a 2-methylpropane-1,3-diyl group).

In the general formula (8), the groups R^{5a} and R^{5b}, q1, and q2 are the same as R^{3a} and R^{3b}, k1, and k2, respectively, described in the general formula (7), also including preferred forms.

Representative examples of the compound represented by the general formula (8) include 9,9-bis(carboxy-C₂₋₆ alkyl)fluorene such as 9,9-bis(2-carboxyethyl)fluorene and 9,9-bis(2-carboxypropyl)fluorene. These fluorenedicarboxylic acids may each be used singly, or two or more thereof may be combined. The fluorenedicarboxylic acid component is preferably 9,9-bis(2-carboxyethyl)fluorene.

### (Another Dicarboxylic Acid Component (B2))

The dicarboxylic acid component (B) may comprise at least one dicarboxylic acid (B2) selected from aliphatic dicarboxylic acid, alicyclic dicarboxylic acid, and aromatic dicarboxylic acid.

Examples of the aliphatic dicarboxylic acid include, but are not particularly limited to, alkanedicarboxylic acid (e.g., C₄₋₁₄ alkanedicarboxylic acid such as succinic acid, adipic acid, sebacic acid, and decanedicarboxylic acid, preferably C₆₋₁₂ alkanedicarboxylic acid), and unsaturated aliphatic dicarboxylic acid (e.g., C₂₋₁₀ alkene-dicarboxylic acid such as maleic acid, fumaric acid, and itaconic acid). The aliphatic dicarboxylic acid is preferably alkanedicarboxylic acid.

Examples of the alicyclic dicarboxylic acid component include, but are not particularly limited to, cycloalkanedicarboxylic acid (e.g., C₅₋₁₀ cycloalkanedicarboxylic acid such as 1,3-cyclohexanedicarboxylic acid and 1,4-cyclohexanedicarboxylic acid), di- or tri-cycloalkanedicarboxylic acid (e.g., decalindicarboxylic acid, norbornanedicarboxylic acid, adamantanedicarboxylic acid, and tricyclodecanedicarboxylic acid), cycloalkenedicarboxylic acid (e.g., C₅₋₁₀ cycloalkene-dicarboxylic acid such as cyclohexenedicarboxylic acid), and di- or tri-cycloalkenedicarboxylic acid (e.g., norbornenedicarboxylic acid).

Examples of the aromatic dicarboxylic acid component include, but are not particularly limited to, monocyclic aromatic dicarboxylic acid [e.g., C₆₋₁₀ arenedicarboxylic acid such as phthalic acid, terephthalic acid, isophthalic acid, and alkylisophthalic acid (e.g., C₁₋₄ alkylisophthalic acid such as 4-methylisophthalic acid)], condensed polycyclic aromatic dicarboxylic acid [e.g., condensed polycyclic C₁₀₋₂₄ arene-dicarboxylic acid such as naphthalenedicarboxylic acid (e.g., 1,5-naphthalenedicarboxylic acid, 1,6-naphthalenedicarboxylic acid, 1,7-naphthalenedicarboxylic acid, 1,8-naphthalenedicarboxylic acid, and 2,6-naphthalenedicarboxylic acid), anthracenedicarboxylic acid, and phenanthrenedicarboxylic acid, preferably condensed polycyclic C₁₀₋₁₆ arene-dicarboxylic acid, further preferably condensed polycyclic C₁₀₋₁₄ arene-dicarboxylic acid], arylarenedicarboxylic acid [e.g., C₆₋₁₀ aryl-C₆₋₁₀ arenedicarboxylic acid such as biphenyldicarboxylic acid (e.g., 2,2′-biphenyldicarboxylic acid, and 4,4′-biphenyldicarboxylic acid)], diarylalkanedicarboxylic acid [e.g., di-C₆₋₁₀ aryl-C₁₋₆ alkane-dicarboxylic acid such as diphenylalkanedicarboxylic acid (e.g., 4,4′-diphenylmethanedicarboxylic acid)], and diaryl ketone dicarboxylic acid [e.g., di-C₆₋₁₀ aryl ketone-dicarboxylic acid) such as diphenyl ketone dicarboxylic acid (e.g., 4,4′-diphenyl ketone dicarboxylic acid)].

The dicarboxylic acid component (B) is not only free carboxylic acid but includes ester-forming derivatives of the dicarboxylic acid, for example, ester [e.g., alkyl ester [e.g., lower alkyl ester (e.g., C₁₋₄ alkyl ester, particularly, C₁₋₂ alkyl ester) such as methyl ester or ethyl ester]], acid halide (e.g., acid chloride), and acid anhydride. These dicarboxylic acid components (B) can each be used singly, or two or more thereof can be used in combination.

### (Method for Producing Polyester-Based Resin)

The polyester-based resin used in the polarizer protective film can be prepared through the reaction of the diol component (A) with the dicarboxylic acid component (B). The method for producing the polyester resin is not particularly limited, and the polyester resin may be prepared by a common method, for example, a transesterification method, a melt polymerization method such as a direct polymerization method, a solution polymerization method, or an interfacial polymerization method. In the polymerization reaction, a transesterification catalyst, a polycondensation catalyst, a heat stabilizer, a light stabilizer, a polymerization modifier, or the like may be used.

Examples of the transesterification catalyst include, but are not particularly limited to, compounds (alkoxide, organic acid salt, inorganic acid salt, metal oxide, etc.) of alkaline earth metals (magnesium, calcium, barium, etc.) or transition metals (manganese, zinc, cobalt, titanium, etc.). Among them, manganese acetate, calcium acetate, or the like can be suitably used.

Examples of the type of the polycondensation catalyst can include, but are not particularly limited to, compounds of the alkaline earth metals, the transition metals, group 13 metals of the periodic table (aluminum, etc.), group 14 metals of the periodic table (germanium, etc.), or group 15 metals of the periodic table (antimony, etc.), more specifically, germanium compounds such as germanium dioxide, germanium hydroxide, germanium oxalate, germanium tetraethoxide, and germanium n-butoxide, antimony compounds such as antimony trioxide, antimony acetate, and antimony ethylene glycolate, and titanium compounds such as tetra-n-propyl titanate, tetraisopropyl titanate, tetra-n-butyl titanate, titanium oxalate, and titanium potassium oxalate. These catalysts may each be used singly, or two or more types thereof may be used as a mixture.

Examples of the heat stabilizer can include, but are not particularly limited to, phosphorus compounds such as trimethyl phosphate, triethyl phosphate, triphenyl phosphate, phosphorus acid, trimethyl phosphite, and triethyl phosphite.

In the reaction, the ratios of the diol component (A) and the dicarboxylic acid component (B) used can be selected from the same ranges as above. If necessary, a predetermined component may be used in excess. For example, a diol component, such as ethylene glycol, capable of being distilled off from the reaction system may be used in excess over the ratio of the unit to be introduced in the polyester-based resin. The reaction may be performed in the presence or absence of a solvent.

The reaction can be performed in an inert gas (nitrogen, helium, etc.) atmosphere. The reaction can also be performed under reduced pressure (e.g., on the order of 1×10² to 1×10⁴ Pa). The reaction temperature depends on a polymerization method, and the reaction temperature in a melt polymerization method, for example, may be on the order of 150 to 300° C., preferably 180 to 290° C., further preferably 200 to 280° C.

The polyester-based resin layer of the present embodiment may be a polymer alloy comprising the fluorene-based polyester resin and a polycarbonate resin. The composition of the polycarbonate resin is not particularly limited as long as the polycarbonate resin is compatible with the fluorene-based polyester resin. For example, bisphenol A, an aromatic polycarbonate resin having a fluorene structure, or an alicyclic polycarbonate resin having an isosorbide structure can be used. If necessary, the polymer alloy may further comprise an additional resin, in addition to the fluorene-based polyester resin, and the polycarbonate resin. Such a polyester resin layer in the form of a polymer alloy permits, for example, improvement in physical characteristics such as toughness and suitable control of optical characteristics such as a property of exerting a phase difference.

In the polymer alloy, the ratios of the fluorene-based polyester resin and the polycarbonate resin are not particularly limited as long as the fluorene-based polyester resin and the polycarbonate resin are compatible with each other. For example, the ratio of the fluorene-based polyester resin is preferably 30% by weight or more, 50% by weight or more, 60% by weight or more, 70% by weight or more, 80% by weight or more, 90% by weight or more, 95% by weight or more, or substantially 100% by weight, based on the total amount of the fluorene-based polyester resin and the polycarbonate resin.

A method for preparing the polymer alloy is not particularly limited and may be a common method, for example, a method of dissolving both the resin components in a solvent, or a method of melt-mixing the resin components using a kneader (or an extruder, for example, a twin-screw extruder). A melt mixing method is preferred because reduction in optical characteristics (e.g., low birefringence and high transparency) caused by a residual solvent after molding into a film can be prevented.

### (Acrylic Resin)

The acrylic resin used in the present embodiment is a polymer comprising a constituent unit derived from (meth)acrylic acid ester, preferably a polymer composed mainly of (meth)acrylic acid ester. The acrylic resin may be a homopolymer of (meth)acrylic acid ester or may be a copolymer with another polymerizable monomer.

Such an acrylic resin may comprise a repeat unit represented by the following general formula (4) having no cyclic structure in the backbone, or a repeat unit represented by the following general formula (5) or (6) having a cyclic structure in the backbone:

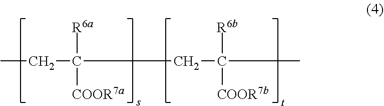

wherein R^{6a} and R^{6b} are the same or different and each represent a hydrogen atom or a C₁₋₈ alkyl group, R^{1a} and R^{7b} are the same or different and each represent a hydrogen atom, a C₁₋₁₈ alkyl group, a C₃₋₁₂ cycloalkyl group, or a substituent containing a C₅₋₁₅ aromatic ring, and s and t each represent a molar fraction with s+t=1,

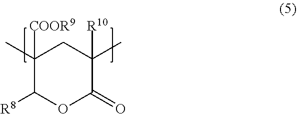

wherein R⁸ represents a hydrogen atom or an organic residue having 1 to 20 carbon atoms, wherein the organic residue optionally contains an oxygen atom, R⁹ represents a hydrogen atom, a C₁₋₁₈ alkyl group, a C₃₋₁₂ cycloalkyl group, or a substituent containing a C₅₋₁₅ aromatic ring, and R¹⁰ represents a hydrogen atom or a C₁₋₈ alkyl group,

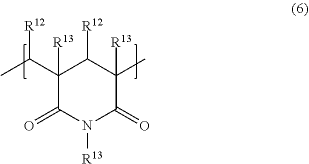

wherein R¹¹ and R¹² are the same or different and each represent a hydrogen atom or a C₁₋₈ alkyl group, and R¹³ represents a hydrogen atom, a C₁₋₁₈ alkyl group, a C₃₋₁₂ cycloalkyl group, or a substituent containing a C₅₋₁₅ aromatic ring.

Examples of the monomer constituting the repeat unit represented by the general formula (4) having no cyclic structure in the backbone include methyl (meth)acrylate, ethyl (meth)acrylate, n-propyl (meth)acrylate, n-butyl (meth)acrylate, t-butyl (meth)acrylate, n-hexyl(meth)acrylate, cyclohexyl (meth)acrylate, 2-ethylhexyl (meth)acrylate, benzyl (meth)acrylate, dicyclopentanyloxyethyl (meth)acrylate, dicyclopentanyl (meth)acrylate, chloromethyl (meth)acrylate, and 2-chloroethyl(meth)acrylate. Two or more types of these monomers may be used.

Among others, polymethyl methacrylate (PMMA) is preferably used as the acrylic resin from the viewpoint of durability. In the present embodiment, the polymethyl methacrylate is not limited as long as the polymethyl methacrylate mainly comprises a repeat unit derived from methyl methacrylate. The polymethyl methacrylate may comprise an additional monomer. The content of the repeat unit derived from methyl methacrylate in the polymethyl methacrylate is preferably 50% by mass or more, more preferably 80% by mass or more, based on the total amount of monomers. The polymethyl methacrylate is industrially produced at a large scale and is most preferred for attaining the object of the present embodiment from the viewpoint of easy availability and cost.

Examples of the cyclic structure of the acrylic resin having the cyclic structure in the backbone include a lactone ring, a glutarimide ring, a glutaric anhydride structure, a maleic anhydride structure, and a N-substituted maleimide structure.

The acrylic resin represented by the general formula (5) having a lactone ring can be obtained by copolymerizing monomers (meth)acrylic acid ester and (meth)acrylic acid ester having a hydroxy group and/or (meth)acrylic acid having a carboxylic acid group, and subjecting the obtained polymer to intramolecular cyclization reaction. Specific examples of the monomer having a hydroxy group include methyl 2-(hydroxymethyl) acrylate, ethyl 2-(hydroxymethyl) acrylate, and methyl 2-(hydroxyethyl) acrylate. Examples of the monomer having a carboxylic acid group include acrylic acid, methacrylic acid, crotonic acid, 2-(hydroxymethyl) acrylic acid, and 2-(hydroxyethyl) acrylic acid. Two or more types of these monomers may be copolymerized. The resulting copolymer may be subjected to cyclization reaction to form an acrylic polymer having a lactone ring in the backbone. Examples of a commercially available product include ACRYVIEWA from Nippon Shokubai Co., Ltd.

The acrylic resin represented by the general formula (6) having a glutarimide ring can be produced by adding primary amine to a (meth)acrylic acid ester polymer, and performing imidation. For example, methyl (meth)acrylate, ethyl (meth)acrylate, butyl (meth)acrylate, isobutyl (meth)acrylate, t-butyl (meth)acrylate, benzyl (meth)acrylate, or cyclohexyl (meth)acrylate can be used as a monomer of such a (meth)acrylic acid ester polymer, and methyl (meth)acrylate is more preferably used. These (meth)acrylic acid esters may each be polymerized singly, or a plurality thereof may be copolymerized in combination.

The acrylic resin having a maleic anhydride structure or a N-substituted maleimide structure is produced by copolymerizing a maleic anhydride or N-substituted maleimide monomer and (meth)acrylic acid ester. Examples of a commercially available product of a maleic acid-modified resin include DELPET 980N manufactured by Asahi Kasei Chemicals Corp. which is maleic acid-modified MAS resin (methyl methacrylate-acrylonitrile-styrene copolymer).

The acrylic resin layer may contain rubber particles in order to impart toughness thereto. The rubber particles blended thereinto can prevent a crack at the time of film transport or at the time of take-up, and can also improve slidability.

The rubber particles may be particles consisting of a layer that exhibits rubber elasticity, or may be particles having a multilayer structure having a layer that exhibits rubber elasticity as well as an additional layer. Examples of the rubber elastic body include olefin-based elastic polymers, diene-based elastic polymers, styrene-diene-based elastic copolymers, and acrylic elastic polymers. Among them, an acrylic elastic polymer is preferably used from the viewpoint of transparency. Examples of the acrylic rubber particles include particles having a 2-layer structure having a hard polymer layer composed mainly of alkyl methacrylate outside a layer of an acrylic elastic polymer, and particles having a 3-layer structure further having a hard polymer layer composed mainly of alkyl methacrylate inside the layer of an acrylic elastic polymer. In the production of the polarizer protective film of the present embodiment, a commercially available acrylic resin blended with acrylic rubber particles may be used, or an acrylic resin blended with commercially available acrylic rubber particles may be prepared by melt kneading.

The acrylic resin layer may be a polymer alloy comprising the acrylic resin and a polyester resin or a polycarbonate resin.

The composition of the polyester resin contained in the acrylic resin layer is not particularly limited as long as the polyester resin is compatible with the acrylic resin. A fluorene-based polyester resin is preferred because durability is excellent and a property of exerting a phase difference can be suitably controlled.

The polycarbonate resin contained in the acrylic resin layer is not particularly limited as long as the polycarbonate resin is compatible with the acrylic resin. An aromatic polycarbonate resin is preferred because durability is excellent. Among others, a fluorene-based polycarbonate resin is more preferred because a property of exerting a phase difference can be suitably controlled.

The polymer alloy may be a polymer alloy comprising the acrylic resin and the polyester resin or the polycarbonate resin as well as an additional resin, if necessary. Such an acrylic resin in the form of a polymer alloy permits, for example, improvement in physical characteristics such as toughness and suitable control of optical characteristics such as a property of exerting a phase difference.

In the polymer alloy, the ratios of the acrylic resin and the polyester resin or the polycarbonate resin are not particularly limited as long as these resins are compatible with each other. The ratio of the acrylic resin is, for example, preferably 30% by weight or more, 50% by weight or more, 60% by weight or more, 70% by weight or more, 80% by weight or more, 90% by weight or more, 95% by weight or more, substantially 100% by weight, based on the total amount of the acrylic resin, the polyester resin, and the polycarbonate resin.

A method for preparing the polymer alloy is not particularly limited and may be a common method, for example, a method of dissolving both the resin components in a solvent, or a method of melt-mixing the resin components using a kneader (or an extruder, for example, a twin-screw extruder). A melt mixing method is preferred because reduction in optical characteristics (e.g., low birefringence and high transparency) caused by a residual solvent after molding into a film can be prevented.

### (Other Resin Layers)

The polarizer protective film of the present embodiment may be provided with a resin layer other than the polyester-based resin layer and the acrylic resin layer. The resin layer other than the polyester-based resin layer and the acrylic resin layer is not particularly limited as long as its material is capable of adhering to a resin layer in contact therewith. A resin contained in such a resin layer is preferably an acetylcellulose-based resin, a cycloolefin-based resin, a polycarbonate-based resin, a polyamide-based resin, or the like excellent in optical characteristics such as transparency. Among them, an acetylcellulose-based resin that exerts less retardation after drawing is more preferred.

A surface treatment layer mentioned later may be formed, if necessary, on the surface of the polarizer protective film of the present embodiment.

The surface treatment layer is intended to improve a function of the polarizer protective film of the present embodiment. Specific examples thereof include layers having one or more of hard coat, antiglare, antireflection, low-reflection, antifouling, and anti-fingerprint effects.

A known material can be used for the layer having the hard coat effect without particular limitations, and a resin compound that is polymerized and/or reacted by heat, chemical reaction, or electron beam, radiation, or ultraviolet irradiation is suitably used. Examples of such a curable resin include (meth)acrylic, epoxy-based, melamine-based, silicone-based, and polyvinyl alcohol-based curable resins. A (meth)acrylic curable resin that is cured by electron beam or ultraviolet ray is preferred because high surface hardness or optical characteristics are obtained. The step of establishing a hard coat layer in the polarizer protective film of the present embodiment may be carried out before a drawing step mentioned later or may be carried out after a drawing step.

The layer having the antiglare effect is not particularly limited. For example, a layer that suppresses glare and reflection by diffusely reflecting incident light from the outside through formed surface asperities can be used as a representative one. Examples of the method for forming the surface asperities include a method of directly roughening the surface by a sandblast method or an embossing method, and a method of allowing a curable resin to contain an inorganic filler (fine particles of silica, etc.) or an organic filler (fine particles of a polystyrene resin, an acrylic resin, etc.) having a diameter on the order of several μm, and curing the resin to establish asperities derived from the inorganic filler or the organic filler.

The layer having the antireflection effect is not particularly limited. For example, a layer that suppresses outside light reflection by coating a dielectric thin film (antireflection film) made of an inorganic material with multiple layers so that reflected light generated at the interface between the thin films and reflected light generated on the outermost surface interfere with each other can be used as a representative one.

The layer having the low-reflection effect is not particularly limited, and a layer that suppresses outside light reflection by reducing a refractive index of the outermost surface can be used. Examples of the method for reducing the refractive index of the outermost surface can include a method of applying a resin containing a low-refractive material typified by a fluorine-based material, and a method of lowering the refractive index by forming a structure finer than the wavelength of visible light on the surface and thereby substantially setting the refractive index of the surface to an average refractive index with air in the fine structure.

The layer having the antifouling effect or the anti-fingerprint effect is not particularly limited, and a layer formed by dry coating or wet coating with a material excellent in water repellency or oil repellency can be used. Specific examples of the material excellent in water repellency or oil repellency can include silicon compounds and fluorine compounds.

### (Ultraviolet Absorber)

The polarizer protective film needs to block ultraviolet ray having a wavelength of 380 nm or less in order to prevent the ultraviolet deterioration of iodine. For the polarizer protective film, a transmittance at 380 nm is reportedly required to be 10% or less, preferably 8% or less. The addition of an ultraviolet absorber is effective for satisfying this requirement. However, a film having a small film thickness cannot obtain a predetermined transmittance unless the ultraviolet absorber is dispersed at a high concentration. A general acrylic resin mentioned later has a low solubility of the ultraviolet absorber, and there is a limitation on the thinning of the film because a necessary amount of the ultraviolet absorber cannot be added to such a thin film.

On the other hand, the polyester-based resin of the present embodiment has a high solubility of the ultraviolet absorber and does not cause bleed-out even when containing a high concentration of the ultraviolet absorber. Thus, the film can be thinned. Hence, the polyester-based resin layer preferably contains an ultraviolet absorber.

This does not inhibit other resin layers from containing an ultraviolet absorber, and other resin layers may contain an ultraviolet absorber.

The ultraviolet absorber is not particularly limited. For example, a known ultraviolet absorber such as a benzophenone-based ultraviolet absorber, a benzotriazole-based ultraviolet absorber, or a triazine-based ultraviolet absorber can be used.

Examples of the benzophenone-based ultraviolet absorber include, but are not particularly limited to, 2-hydroxy-4-pentyloxybenzophenone, 2-hydroxy-4-octyloxybenzophenone, 2-hydroxy-4-octyloxy-4′-methoxybenzophenone, 2-hydroxy-4-cyclohexyloxybenzophenone, and 2-hydroxy-4-octyloxy-4′-chlorobenzophenone. Among them, 2-hydroxy-4-octyloxybenzophenone is preferred.

Examples of the benzotriazole-based ultraviolet absorber include, but are not particularly limited to, phenol, 2-(2H-benzotriazol-2-yl)-4-methyl, phenol, 2-(2H-benzotriazol-2-yl)-4,6-bis(1-methyl-1-phenylethyl), phenol, 2-(5-chloro-2H-benzotriazol-2-yl)-6-(1,1-dimethylethyl) 4-methyl, 2phenol, 2-(2H-benzotriazol-2-yl)-4-(1,1, 3,3-tetramethylbutyl), phenol, 2,2′-methylene-bis(6-(2H-benzotriazol-2-yl)-4-(1, 1, 3,3-tetramethylbutyl), phenol, 2-(2H-benzotriazol-2-yl)-4-methyl-6-dodecyl, 2-(2-hydroxy-5-tert-butylphenyl)-2H-benzotriazole, benzenepropanoic acid, 3-(2H-benzotriazol-2-yl)-5-(1,1-dimethylethyl)-4-hydroxy-C₇-C₉ alkyl ester, 2-(2H-benzotriazol-2-yl)-4,6-bis(1-phenylethyl) phenol, 2-(2H-benzotriazol-2-yl)-6-(1-methyl-1-phenylethyl)-4-(1, 1, 3,3-tetramethylbutyl) phenol, 2,2′-methylenebis [6-(2H-benzotriazol-2-yl)-4-(1, 1, 3,3-tetramethylbutyl) phenol], 2,2′-methylenebis [4-(1, 1, 3,3-tetramethylbutyl)-6-[(2H-benzotriazol-2-yl) phenol], 2-(2-hydroxy-3-α-cumyl-5-alkylphenyl)-2H-benzotriazole, octyl-3-[3-tert-butyl-4-hydroxy-5-(5-chloro-2H-benzotriazol-2-yl)phenyl]propionate, and 2-ethylhexyl-3-[3-tert-butyl-4-hydroxy-5-(5-chloro-2H-benzotriazol-2-yl)phenyl]propionate. Among them, phenol, 2,2′-methylene-bis(6-(2H-benzotriazol-2-yl)-4-(1,1,3,-tetramethylbutyl) is preferred.

Examples of the triazine-based ultraviolet absorber include 2-[4-[(2-hydroxy-3-(2′-ethyl) hexyl)oxy]-2-hydroxyphenyl]-4,6-bis(2,4-dimethylphenyl)-1, 3,5-triazine, 2,4-bis(2-hydroxy-4-butyloxyphenyl)-6-(2,4-bis-butyloxyphenyl)-1, 3,5-triazine, 2, 4,6-tris(2-hydroxy-4-hexyloxy-3-methylphenyl)-1, 3,5-triazine, phenol, and 2-(4,6-diphenyl-1, 3,5-triazin-2-yl)-5-hexyloxy. Among them, 2-[4-[(2-hydroxy-3-(2′-ethyl) hexyl)oxy]-2-hydroxyphenyl]-4,6-bis(2,4-dimethylphenyl)-1,3,5-triazine is preferred.

These ultraviolet absorbers may each be used singly, or two or more thereof may be used in combination. Among them, an ultraviolet absorber having a maximum absorption wavelength at 320 to 400 nm is preferred. A higher molar absorption coefficient at 380 nm is more preferred because the amount of the ultraviolet absorber added is smaller. It is preferred to select the ultraviolet absorber by also taking into consideration staining ascribable to absorption around 400 nm.

In the case of adding the ultraviolet absorber to the polyester-based resin layer or other resin layers, the amount of the ultraviolet absorber added depends on the type thereof and therefore, cannot be generalized. The amount of the ultraviolet absorber added can be, for example, 0.1% by mass to 30% by mass and is preferably 1% by mass to 20% by mass, more preferably 3% by mass to 10% by mass, based on the whole resin layer concerned. When the amount is equal to or more than the lower limit value of the range described above, ultraviolet absorption performance can be improved. When the amount is equal to or less than the upper limit value, a polarizer protective film that is more transparent, and is less stained, and is also excellent in durability can be obtained.

### (Other Additives)

The polyester-based resin layer and/or other resin layers may contain, if necessary, various additives in addition to the ultraviolet absorber. Examples of such an additive include, but are not particularly limited to, antistatic agents, weathering agents, flame retardants, heat stabilizers, antioxidants, anti-gelling agents, and surfactants.

Further, slidability may be imparted, if necessary, to the film of the present embodiment. Examples of the method for imparting slidability include conventionally known techniques, for example, a method of adding inorganic or organic fine particles of clay, mica, titanium oxide, calcium carbonate, silica, kaolin, acryl, polystyrene, polydivinylbenzene, or the like, and a method of coating film surface with a polymer containing a surfactant, a mold release agent, or fine particles during film formation or after film formation.

A method for adding such an additive is not particularly limited, and the additive can be added, for example, by supplying the additive together with a starting material resin to a single-screw or twin-screw extrusion apparatus, and melt-kneading the mixture. The addition of the additive may be performed in an extrusion apparatus different from a melt film formation apparatus before film formation, or may be performed in an extrusion apparatus attached to a T die at the time of film formation. The latter approach which can continuously perform melt kneading and film formation is industrially advantageous. Kneading using a twin-screw extrusion apparatus is suitable for sufficiently dispersing the additive.

### [Other Forms of Polarizer Protective Film]

The polarizer protective film for which the polyester-based resin layer comprising a fluorene-based polyester resin and the acrylic resin layer comprising an acrylic resin are essential is described above. In other forms, a polycarbonate resin layer comprising a polycarbonate resin may be used instead of the polyester-based resin layer comprising a fluorene-based polyester resin. In the present specification, the “polyester-based resin layer” also encompasses the “polycarbonate resin layer”.

A multilayer film having the polycarbonate resin layer and the acrylic resin layer comprising an acrylic resin can also produce similar effects to those of the multilayer polarizer protective film having the polyester-based resin layer. Specifically, the polycarbonate resin contained therein improves toughness over a single film made of an acrylic resin, and an ultraviolet absorber can be contained in the polycarbonate resin having high affinity for the ultraviolet absorber.

The polycarbonate resin is not particularly limited, and various resins can be used. An aromatic polycarbonate resin is preferred because of high moldability and excellent toughness. Particularly, a bisphenol A-based polycarbonate resin is preferred from the viewpoint that this resin is used for general purposes and can reduce cost. A polycarbonate resin having a fluorene skeleton in a side chain is also preferred from the viewpoint that a phase difference can be lowered.

### (Method for Producing Multilayer Film)

The method for producing the multilayer film by a coextrusion method according to the present embodiment will be described. First, pellets of a polyester-based resin and resins for use in other layers are dried in a dryer such that their moisture contents are less than 100 ppm. Subsequently, the pellets of each resin and an additive are measured, mixed, and supplied to an extruder. The respective layers are combined using a multilayer feed block and melt-extruded into a sheet from a slit-like die. The sheet in a melted state is further allowed to adhere to a casting roll by use of a static application method, and solidified by cooling to obtain a multilayer film. Alternatively, a multi-manifold die may be used instead of using the multilayer feed block.

The melting temperature of each resin is preferably a temperature higher by 50 to 180° C. than the glass transition temperature (Tg), more preferably a temperature higher by 80 to 150° C. than the glass transition temperature (Tg). When the melting temperature in an extruder is higher by 50° C. or more than the glass transition temperature, the fluidity of the resin tends to be more improved. When the melting temperature in an extruder is lower by 180° C. or less than the glass transition temperature, the deterioration of the resin at the time of melting tends to be suppressed. The resin is melted in an extruder and

continuously sent, if necessary, to a filter and a die via a gear pump. Each melted resin is subjected to high-precision filtration in order to remove foreign matter contained in the resin. A filter medium for use in the high-precision filtration of the melted resin is not particularly limited, and a filter medium of sintered stainless is excellent in removal performance and is thus suitable.

The multilayer film of the present embodiment is not particularly limited by its layer configuration and may have, for example, a 2-resin 2-layer structure of the polyester-based resin/a resin other than the polyester, a 2-resin 3-layer structure of the polyester-based resin/a resin other than the polyester/the polyester-based resin, or a 2-resin 3-layer structure of a resin other than the polyester/the polyester-based resin/a resin other than the polyester. In this context, when the resin other than the polyester forms only one layer, the resin is an acrylic resin. In the case of two or more layers, a resin of at least one layer can be an acrylic resin. A 3-layer structure which has the same resin in outermost layers is more effective than a 2-layer structure for preventing the multilayer film from curling, and the outermost layers having the same or similar thickness are effective because contractile force is canceled. For use as the polarizer protective film of the present embodiment, an outermost layer adhering to a PVA film may be the polyester-based resin or may be a resin other than the polyester. Use of the acrylic resin having high surface hardness and a low refractive index as an outermost layer and the polyester-based resin as a core layer is effective for preventing scratch and lowering a surface refractive index.

The thickness ratio of each layer in the multilayer film of the present embodiment can be determined from a draw ratio as a drawing condition designed such that characteristics (in-plane phase difference Ro, phase difference Rth in a thickness direction, total light transmittance, spectral transmittance at 380 nm, flex resistance, etc.) of the film after drawing satisfy the desired values.

Specifically, the thickness ratio of the polyester-based resin layer to the whole is preferably 1% or more and 30% or less, more preferably 3% or more and 25% or less, further preferably 5% or more and 20% or less. Flex resistance and ultraviolet absorption performance tend to be more improved with increase in thickness ratio of the polyester-based resin layer. A phase difference in a thickness direction tends to be more decreased with decrease in thickness ratio of the polyester-based resin layer. In addition, production cost tends to be reduced.

The thickness ratio of the layer other than the polyester-based resin layer, such as an acrylic resin layer, in the 2-resin 3-layer structure or the like to the whole is preferably 10% or more and 80% or less, more preferably 15% or more and 75% or less, further preferably 20% or more and 70% or less, on a layer basis. A phase difference in a thickness direction tends to be more decreased with increase in thickness ratio of the resin layer other therethan. In addition, production cost tends to be reduced. Furthermore, flex resistance and ultraviolet absorption performance tend to be more improved. Flex resistance and ultraviolet absorption performance tend to be more improved with decrease in thickness ratio of the resin layer other therethan.

The total thickness of the multilayer film of the present embodiment is preferably 5 to 90 μm, more preferably 10 to 80 μm, further preferably 20 to 50 μm. The multilayer film having the polyester-based resin layer can achieve such a much thinner polarizer protective film.

The multilayer film of the present embodiment is excellent in interfacial adhesion between the polyester-based resin layer and an additional resin layer such as an acrylic resin layer. In the case of using the acrylic resin in the additional resin layer, the acrylic resin and the polyester-based resin has a small difference in solubility parameter and have been confirmed to adhere to each other without the use of an adhesive resin.

The multilayer film of the present embodiment may be an undrawn film or may be a drawn film from the viewpoint of mechanical characteristics. Drawing treatment is effective as a film thinning approach. When an undrawn film has a thickness of roughly 50 μm or larger, the film thickness can be controlled by sandwich between nip rolls after casting from a T die. Thus, film thickness accuracy is improved. A thin film with good film thickness accuracy can be obtained by selecting drawing conditions under which uniform drawing stress is obtained, and performing drawing treatment.

Molding by drawing can be performed while the multilayer film formed by the coextrusion method is heated to an appropriate temperature between the respective melting points and the respective glass transition points of the polyester-based resin and other resins. The drawing may be biaxial drawing or uniaxial drawing. For use as the polarizer protective film of the present embodiment, biaxial drawing is preferred because less retardation ascribable to drawing is exerted. The biaxial drawing can draw the film in two directions, i.e., longitudinally and transversely, and in-plane retardation Ro can be canceled longitudinally and transversely and becomes a value close to zero. However, retardation Rth in a thickness direction cannot be canceled. It is therefore desirable to use a resin having minimum intrinsic birefringence. Rth needs to fall within an acceptable range by a film thickness and drawing conditions. The biaxial drawing may be equal drawing having equal strength and contraction between longitudinally and transversely, or biased drawing differing in strength and contraction between longitudinally and transversely.

The retardation is preferably Ro(550) of 0 nm or more and 50 nm or less and Rth(589) of −50 nm or more and 50 nm or less, more preferably Ro(550) of 0 nm or more and 40 nm or less and Rth(589) of −40 nm or more and 40 nm or less, further preferably Ro(550) of 0 nm or more and 10 nm or less and Rth(589) of −20 nm or more and 20 nm or less, for use as the polarizer protective film. When the retardation falls within the range described above, a phase difference is small both in an in-plane direction and in a thickness direction and the polarizer protective film is more useful. In the present embodiment, Ro(550) refers to an in-plane phase difference at 550 nm, and Rth(589) refers to a phase difference in a thickness direction at 589 nm.

The spectral transmittance of the multilayer film at a wavelength of 380 nm is preferably 10% or less, more preferably 7.5% or less, further preferably 5.0% or less. The total light transmittance of the multilayer film is preferably 85% or more, more preferably 90% or more, further preferably 95% or more. When the spectral transmittance at a wavelength of 380 nm, and the total light transmittance fall within the ranges described above, the polarizer protective film can be more suitably used.

As for a draw ratio, the draw ratio in each direction in uniaxial drawing or biaxial drawing may be 1.1 to 3.5 times, preferably 1.2 to 3.0 times, further preferably 1.3 to 2.5 times. For example, the biaxial drawing may be equal drawing (e.g., drawing 1.2 to 3 times in both the longitudinal and transverse directions) or biased drawing (e.g., drawing 1.1 to 2 times in the longitudinal direction and 2 to 4 times in the transverse direction). When the draw ratio is equal to or more than the lower limit value described above, the thickness of the resulting multilayer film tends to be decreased. When the draw ratio is equal to or less than the upper limit value described above, the phase difference of the resulting multilayer film is easily decreased. Also, the resulting multilayer film tends to be more prevented from being broken.

The drawing temperature is preferably Tg−10° C. or higher, more preferably Tg−5° C. or higher, particularly preferably Tg ° C. or higher, and preferably Tg+20° C. or lower, more preferably Tg+15° C. or lower, particularly preferably Tg+10° C. or lower. In this context, Tg refers to a higher temperature among the glass transition temperatures of the polyester-based resin and other resins. Minimum difference ΔTg among the glass transition temperatures of the polyester-based resin and other resins is preferred. Preferably, ΔTg is 10° C. or less. If ΔTg exceeds 20° C., any resin might fall outside the preferred range of the drawing temperature. When the drawing temperature is equal to or more than the lower limit value described above, the film can be uniformly drawn and the film thickness tends to be uniform. When the drawing temperature is equal to or less than the upper limit value described above, the phase difference of the resulting multilayer film is easily decreased. Also, the resulting multilayer film tends to be more prevented from being broken.

Preheating before drawing and heat fixation after drawing can reduce variation in phase difference value after drawing and can reduce variation in orientation angle associated with bowing. Either preheating or heat fixation may be performed, and it is more preferred to perform both. Such preheating and heat fixation are preferably performed by holding with clips, i.e., preferably performed continuously with drawing.

The preheating temperature is preferably Tg−5° C. to Tg+40° C., more preferably Tg to Tg+30° C. The preheating time is 1 second to 10 minutes, more preferably 5 seconds to 4 minutes, further preferably 10 seconds to 2 minutes.

The heat fixation can be carried out at Tg−5° C. to Tg+25° C., more preferably Tg to Tg+15° C. The heat fixation may be performed at a temperature lower by 1° C. to 50° C. than the drawing temperature and is more preferably performed at a temperature lower by 2° C. to 40° C., further preferably by 3° C. to 30° C., than the drawing temperature. The heat fixation temperature is further preferably equal to or lower than the drawing temperature and equal to or lower than Tg. The heat fixation time is preferably 1 second to 10 minutes, more preferably 5 seconds to 4 minutes, further preferably 10 seconds to 2 minutes. For the heat fixation, the width of a tenter is preferably decreased by approximately 0 to 10% from the width after the completion of drawing.

The melting temperature of each resin to be extruded is preferably Tg+80° C. or higher, more preferably Tg+100° C. or higher, and preferably Tg+180ºC or lower, more preferably Tg+150° C. or lower. When the melting temperature of the resin to be extruded is equal to or higher than the lower limit value of the range described above, the fluidity of the resin can be sufficiently enhanced and moldability can thus be favorable. When the melting temperature is equal to or lower than the upper limit value, the deterioration of the resin can be suppressed.

A drawing method is not particularly limited and may be a tenter method (also called flat method) or a tube method for biaxial drawing. A tenter method excellent in drawing thickness uniformity is preferred. The biaxial drawing may be sequential biaxial drawing or may be simultaneous biaxial drawing. Simultaneous biaxial drawing is more preferred because less retardation is exerted.

The multilayer film is superior in mechanical properties (e.g., tensile strength, tensile elongation, and fragility) to a general acrylic resin film and is therefore capable of having a small film thickness. Drawing treatment more enhances tensile strength and in addition, can form a thin film having good handleability without a crack or the like because of the absence of fragility. The multilayer film of the present embodiment may be produced with a thickness of 25 μm or smaller.

### [Polarizing Plate]

Next, the polarizing plate of the present embodiment will be described with reference to FIGS. 2A and 2B. This polarizing plate comprises the polarizer protective film described above. Each of FIGS. 2A and 2B is a cross-sectional view schematically illustrating one form of the polarizing plate.

Polarizing plate 20 shown in FIG. 2A is a laminate of phase difference film 21, polarizer 23, and polarizer protective film 10 in this order. As shown in this drawing, adhesive layer 22 may be disposed between the phase difference film 21 and the polarizer 23, and adhesive layer 24 may be disposed between the polarizer 23 and the polarizer protective film 10.

Polarizing plate 30 shown in FIG. 2B is a laminate of phase difference film 31, polarizer protective film 10, polarizer 34, and polarizer protective film 10 in this order. Adhesive layer or pressure-sensitive adhesive layer 32 may be disposed between the phase difference film 31 and the polarizer protective film 10, and adhesive layer 33 or 35 may be disposed between the polarizer 34 and the polarizer protective film 10.

The polarizer protective film 10 may be subjected to corona treatment, plasma treatment, or surface modification treatment with an aqueous solution of a strong base such as sodium hydroxide or potassium hydroxide in order to improve adhesion to the polarizer 23 or 34. Such surface modification treatment may be performed after a film formation step or may be performed after a drawing step.

The polarizer 23 or 34 is not particularly limited as long as the polarizer is a conventionally known one. Examples thereof include: films obtained by subjecting hydrophilic polymer films such as polyvinyl alcohol films, partially formalized polyvinyl alcohol films, or ethylene-vinyl acetate copolymer-based partially saponified films to staining treatment with iodine or a dichroic substance such as a dichroic dye and drawing treatment; and polyene-based oriented films such as dehydration treatment products of polyvinyl alcohol and dehydrochlorination treatment products of polyvinyl chloride. Other examples thereof include polarizers obtained by staining polyvinyl alcohol films with iodine, followed by uniaxial drawing.

The polarizer protective film described above can be used as the polarizer protective film 10. The polarizer protective film 10 and the polarizer 23 or 34 formed from a polyvinyl alcohol-based resin or the like may be laminated through an ultraviolet-curable adhesive (adhesive layer 24, 33, or 35).

### (Ultraviolet-Curable Adhesive)

As an adhesive that is used for laminating the polarizer protective film and the polarizer, a conventional aqueous adhesive, for example, polyvinyl alcohol or polyvinyl butyral, for use in TAC films cannot be used, from the viewpoint of productivity, due to a slow drying rate of water because a polyethylene terephthalate resin or an acrylic resin film has low moisture permeability. Hence, it is possible to use an ultraviolet-curable adhesive.

Characteristics necessary for the ultraviolet-curable adhesive for use in a polarizing plate production process are adhesive strength as a matter of course, and have many requirements such as the absence of a solvent, the viscosity of a coating liquid, an integral quantity of light, heat resistance, and a coating film thickness. Particularly, the viscosity of a coating liquid, the integral quantity of light, and the coating film thickness influence a production rate and are therefore regarded as being important.

The multilayer film of the present embodiment can employ an ultraviolet-curable adhesive for lamination with the polarizing plate. Examples of the ultraviolet-curable adhesive that may be used in the present embodiment include, but are not particularly limited to, a radical polymerizable composition containing a urethane acrylate oligomer which is a reaction product of aromatic polyester polyol, polyfunctional isocyanate, and hydroxy group-containing acrylate, and monofunctional acrylate. A composition containing a urethane acrylate oligomer which is a reaction product of polyester polyol having a 9,9-bis(aryl) fluorene skeleton, a diisocyanate compound, and a hydroxy group-containing acrylate compound, and a monofunctional acrylate compound is preferred. For such a composition, the contents disclosed in detail in Japanese Patent Laid-Open No. 2018-087284 can be incorporated herein by reference.

The ultraviolet-curable adhesive contains a urethane acrylate oligomer and is therefore excellent in adhesion between the protective film and a PVA polarizer and excellent in curability. Furthermore, the urethane acrylate oligomer has a 9,9-bis(aryl) fluorene skeleton and an alicyclic carboxylic acid structure in the backbone and is thereby excellent in adhesion and also excellent in heat resistance, water resistance, and low shrinkage on curing. Examples of the compound that forms the 9,9-bis(aryl) fluorene skeleton include 9,9-bis [4-(2-hydroxyethoxy)phenyl]fluorenes and 9,9-bis [4-(2-hydroxyethoxy) naphthyl]fluorenes. Examples of the compound that forms the alicyclic carboxylic acid structure include 1,4-cyclohexanedicarboxylic acid.

Alicyclic diisocyanate is used as the polyfunctional isocyanate in the ultraviolet-curable adhesive, which is thereby excellent in heat resistance, water-resistant adhesion, and coating film flexibility. For example, hydrogenated diphenylmethane diisocyanate, hydrogenated xylylene diisocyanate, isophorone diisocyanate, norbornene diisocyanate, or 1,3-bis(isocyanatomethyl)cyclohexane can be used as the alicyclic diisocyanate.

For example, 2-hydroxyethyl acrylate or 2-hydroxypropyl acrylate excellent in curability can be used as the hydroxy group-containing acrylate in the ultraviolet-curable adhesive.

The ultraviolet-curable adhesive employs monofunctional acrylate as a diluent monomer and is thereby viscosity-adjusted. For example, benzyl acrylate, dicyclopentenyl acrylate, dicyclopentenyloxyethyl acrylate, or phenoxyethyl acrylate having coatability, water resistance, small shrinkage on curing, and excellent adhesion can be used as the monofunctional acrylate. Use of such monofunctional acrylate enables a viscosity to be adjusted in a wide range without impairing an adhesive property. The monofunctional acrylate preferably has a low viscosity from the viewpoint of a coating speed and preferably has a viscosity in the range of 100 to 500 mPa·s at ordinary temperature (25° C.).

The ultraviolet-curable adhesive may contain a photo radical polymerization initiator. Examples of the photo radical polymerization initiator include Irgacure 184, 907, 651, 1700, 1800, 819, 369, 261, DAROCUR-TPO (Ciba Specialty Chemicals), Darocure 1173 (Merck KGAA), Esacure KIP150, TZT (DKSH Japan K.K.), and Kayacure BMS and Kayacure DMBI (Nippon Kayaku Co., Ltd.). For efficiently curing the ultraviolet-curable adhesive, it is preferred to select a photo radical polymerization initiator having an absorption wavelength different from that of the polarizer protective film.

The integral quantity of light of ultraviolet ray is not particularly limited, and exposure is preferably performed by irradiation with light having a wavelength of 200 to 450 nm and an illuminance of 1 to 500 mW/cm² so as to attain 10 to 5000 mJ/cm². When the integral quantity of light is 10 mJ/cm² or more, the curing of an ultraviolet-curable composition is more accelerated and required performance tends to be able to be exerted more effectively and reliably. On the other hand, when the integral quantity of light is 5000 mJ/cm² or less, an irradiation time can be more shortened and productivity is further improved. The integral quantity of light is more preferably 100 to 500 mJ/cm², further preferably 200 to 300 mJ/cm². For example, a high-pressure mercury lamp, a low-pressure mercury lamp, a metal halide lamp, or an excimer lamp is preferably used as a light irradiation apparatus.

### [Image Display Apparatus]

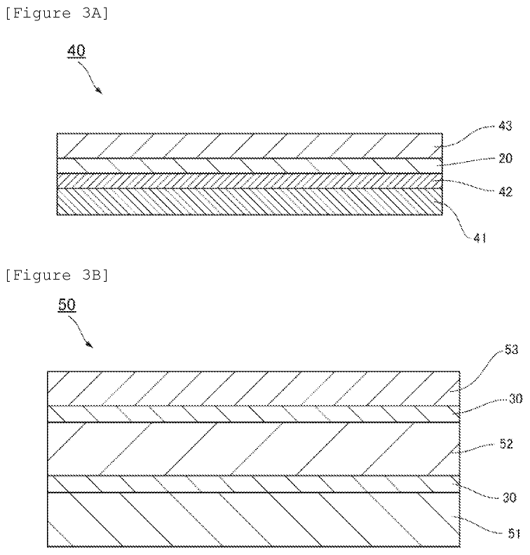

Next, the image display apparatus of the present embodiment will be described with reference to FIGS. 3A and 3B. The image display apparatus of the present embodiment is not particularly limited as long as the image display apparatus comprises the polarizing plate. Examples thereof include organic electroluminescence (EL) display apparatuses and liquid crystal display apparatuses. The image display apparatus is not only an apparatus that is distributed as a final product in itself to the market but may be a portion of an information processing apparatus mentioned later, for example, a smartphone. FIG. 3A is a cross-sectional view schematically illustrating an organic EL display apparatus according to one aspect of the present embodiment. FIG. 3B is a cross-sectional view schematically illustrating a liquid crystal display apparatus according to one aspect of the present embodiment.

As shown in FIG. 3A, organic EL display apparatus 40 has organic EL display panel 41, polarizing plate 20 comprising the polarizer protective film 10 of the present embodiment, and front panel 43 in this order. In the organic EL display apparatus 40, use of polarizing plate 20 having polarizer protective film 10 can prevent the polarizing plate 20 from being deteriorated by ultraviolet ray or moisture permeation and achieves excellent mechanical strength against flex and a thinner polarizing plate.

The organic EL display apparatus 40 may optionally have an additional configuration such as touch sensor 42. The organic EL display apparatus 40 equipped with the touch sensor 42 functions as an information input interface, in addition to a function as a display apparatus. The respective layers constituting the organic EL display apparatus 40 may be joined to each other using a pressure-sensitive adhesive or a tackiness agent.

As shown in FIG. 3B, liquid crystal display apparatus 50 has light source 51, polarizing plate 30, liquid crystal panel 52, polarizing plate 30, and front panel 53 in this order. The light source 51 may be a direct-lit system in which light sources are evenly arranged immediately beneath the liquid crystal panel, or may be an edge-lit system having a reflector and a light guide panel. Although FIG. 3B shows the front panel 53, the liquid crystal display apparatus 50 may have no front panel 53. The liquid crystal display apparatus 50 may further have a touch sensor (not shown).

The touch sensor may be a so-called in-cell touch sensor which is disposed inside the organic EL display panel 41 or the liquid crystal panel 52, or may be a so-called on-cell touch sensor which is disposed between the organic EL display panel 41 and the polarizing plate 20 or between the liquid crystal panel 52 and the polarizing plate 30. The in-cell or on-cell touch sensor is capable of reducing a thickness or a weight as compared with a conventionally dominant external touch sensor.

The system of the touch sensor is not particularly limited. For example, any of conventionally known capacitive, optical, ultrasonic, electromagnetic induction, and resistive systems can be used. Among them, a capacitive touch sensor having at least one conductive film is preferred because a plurality of locations can be detected by touch at the same time and durability is excellent.

A conductive layer formed on the surface of a base material film can be used as the conductive film. The base material film is not particularly limited as long as the conductive layer can be formed. A polyester resin, a cycloolefin resin, a polycarbonate resin, or a polyimide resin is preferably used because of high processability, etc.

The conductive layer to be formed in the conductive film is not particularly limited as long as the conductive layer has high conductivity and high transparency. The conductive layer may comprise, for example, a plurality of metal thin wires formed therein.

The metal thin wires are preferably silver, copper, or an alloy comprising at least one thereof because of excellent conductivity. Use of such a metal material excellent in conductivity can confer sufficient conductivity even if the line width of the metal thin wires is thinned in order to enhance transparency.

A method for forming the metal thin wires is not particularly limited. For example, a formation method of pattern-exposing a layer made of a photosensitive material such as silver halide, followed by development treatment, a formation method of pattern-etching a conductive layer formed by deposition, sputtering, metal foil lamination, or the like, or a formation method of printing metal ink containing metal nanowires by an inkjet method or a method such as screen printing, can be used.

The line width of the metal thin wires is not particularly limited and is preferably 1 to 20 μm, more preferably 1 to 10 μm, further preferably 1 to 5 μm, from the viewpoint of exerting high conductivity and rendering the metal thin wires less visible.

The conductive layer to be formed in the conductive film may comprise indium tin oxide (ITO), antimony-doped tin oxide (ATO), a conductive polymer, or a carbon-based material, in addition to the formed metal thin wires mentioned above. Use of such a material can prepare a transparent conductive layer having sufficient conductivity even if the transparent conductive layer is thinned so as to have a thickness that attains transparency. Among them, indium tin oxide is preferably used because of having high conductivity and transparency. Such a transparent conductive layer can be formed as a thin film by a method such as deposition or sputtering and may be further patterned, if necessary, after thin film formation.

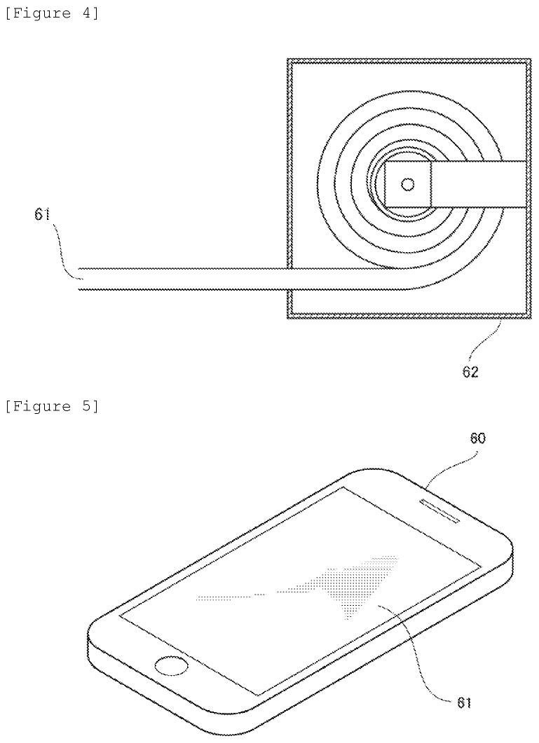

The screen of the image display apparatus is not limited by a rectangular shape and may have a round, oval, or polygonal (e.g., triangular or pentagonal) shape. The image display apparatus can further have flexibility, and its shape may be changed such that the image display apparatus is arched, bent, wound, or folded. For example, as shown in FIG. 4, the mage display apparatus includes a rollable display that can be used such that a roll of image display apparatus 61 housed in image display apparatus housing 62 is taken out.

The image display apparatus of the present embodiment has less change in optical characteristics such as staining in a high-temperature environment and as such, can be suitably used, for example, as an in-car image display apparatus such as a car navigation apparatus, a back monitor, or a head-up display.

### [Information Processing Apparatus]

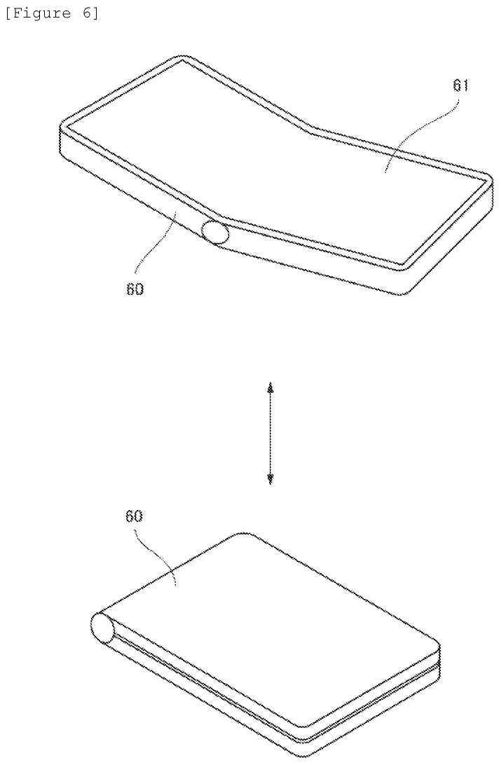

Next, the information processing apparatus of the present embodiment will be described with reference to FIG. 5. This drawing is a perspective view schematically showing information processing apparatus 60 of the present embodiment. The information processing apparatus 60 comprises the image display apparatus having the polarizing plate. The information processing apparatus 60 is a smartphone having image display apparatus 61. The image display apparatus 61 can adopt, for example, the configuration of the organic EL display apparatus 40 or the liquid crystal display apparatus 50 mentioned above.

Examples of such information processing apparatus 60 include smartphones as well as, but are not particularly limited to, various apparatuses capable of processing information, such as personal computers and tablet terminals. The thinness of the polarizing plate of the present embodiment is exploited, particularly, for a personal computer, a smartphone, a tablet terminal, or the like desired to be thinned or miniaturized. A much thinner polarizing plate can be achieved for a personal computer, a smartphone, a tablet terminal, or the like that is carried to various locations such as outdoors or indoors and used.

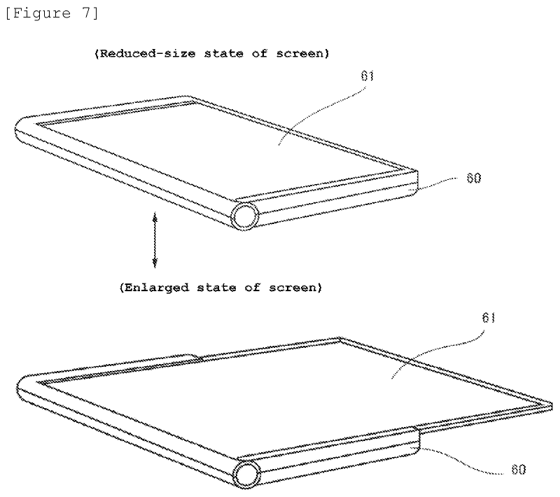

Further examples of the information processing apparatus 60 include terminals such as a foldable smartphone that has refrangible image display apparatus 61 and can be folded (FIG. 6), and a rollable smartphone that can be used such that a roll of image display apparatus 61 housed therein is taken out (FIG. 7).

The image display apparatus 61 may also have a function as an input or output interface of the information processing apparatus and may have a function as an output interface which outputs various processing results of the information processing apparatus, or an input interface, such as a touch panel, which performs operation for the information processing apparatus. Other configurations of the information processing apparatus are not particularly limited, and the information processing apparatus can typically have a processor, a communication interface that controls wired or wireless communication, an input or output interface other than the image display apparatus, a memory, a storage, and one or more communication buses for mutually connecting these components.

### EXAMPLES

Hereinafter, the present invention will be described in detail with reference to Examples. However, the present invention is not limited by Examples given below.

### [Evaluation Method]

### (Glass Transition Temperature (Tg))

A differential scanning calorimeter (“DSC 6220” manufactured by Seiko Instruments Inc.) was used. A sample was placed in an aluminum pan, and Tg was measured in the range of 30° C. to 200° C. in accordance with JIS K 7121.

### (Molecular Weight)

Gel permeation chromatography (manufactured by Tosoh Corp., “HLC-8120GPC”) was used. A sample was dissolved in chloroform, and polystyrene-based weight-average molecular weight Mw was measured.

### (Phase Difference)

A retardation measurement apparatus (“RETS-100” manufactured by Otsuka Electronics Co., Ltd.) was used. In-plane phase difference Ro(550) at a wavelength of 550 nm and phase difference Rth(589) in a thickness direction at a wavelength of 589 nm of a film were measured at a measurement temperature of 20° C.

### (Average Thickness)

A thickness gauge (“Micrometer” manufactured by Mitsutoyo Corp.) was used. Three equally spaced points between chucks were measured in the longitudinal direction of a film, and an average value thereof was calculated.

### (Flex Resistance)

A 15 mm×30 mm piece cut out of a film was subjected to a bending test at room temperature of 23° C. under conditions involving a bending radius of 2 mm, a bending rate of 30 times/min, and a bending angle of 180° in a bending tester (manufactured by Yuasa System Co., Ltd., “DMLHP-CS”). The test was conducted until the number of bends reached 200000 times. The number of bends leading to complete break was counted, and flex resistance was evaluated as follows.
⊚: 200000 times or more
◯: 10000 times or more and less than 200000
x: Less than 10000

### (Peel Strength Against PVA)

An ultraviolet-curable adhesive mentioned later was applied at a thickness of 5 μm to the surface of a polarizer protective film prepared in each Example. Subsequently, an aqueous PVA solution (“JC-40” manufactured by JAPAN VAM & POVAL Co., Ltd.) was applied onto an appropriate base material and dried to prepare a PVA film, which was laminated onto the adhesive layer using a laminator. Then, the adhesive was cured by ultraviolet irradiation with a high-pressure mercury lamp such that the integral quantity of light was 300 (mJ/cm²) to prepare a test specimen.

For each test specimen, 180-degree peel strength at the interface between the polarizer (PVA film) and the polarizer protective film was measured in accordance with JIS K 6854-2, and peel strength against PVA was evaluated as follows from the measured value.
◯: The 180-degree peel strength was 3 (N/25 mm) or more.
x: The 180-degree peel strength was less than 3 (N/25 mm).

### (Spectral Transmittance)

A spectral transmittance at 380 nm was measured using “U-3010” (manufactured by Hitachi, Ltd.).

### [Starting Material]

### (Synthesis Example 1: FDPM: 9,9-bis(2-methoxycarbonylethyl)fluorene[dimethyl ester of 9,9-bis(2-carboxyethyl)fluorene (or fluorene-9,9-dipropionic acid)])

200 mL of 1,4-dioxane and 33.2 g (0.2 mol) of fluorene were placed in a reactor, and the fluorene was dissolved by stirring. Then, 3.0 mL of a solution containing 40% by mass of trimethylbenzylammonium hydroxide in methanol (“Triton B40” manufactured by Tokyo Chemical Industry Co., Ltd.) was added dropwise thereto in a state cooled to 10° C., and the mixture was stirred for 30 minutes. Next, 37.9 g (0.44 mol) of methyl acrylate was added thereto, and the mixture was stirred for approximately 3 hours. After the completion of the reaction, the reaction mixture was washed by the addition of 200 mL of toluene and 50 mL of 0.5 N hydrochloric acid. The aqueous layer was removed, and the organic layer was then washed three times with 30 mL of distilled water. The solvent was distilled off to obtain 84.0 g of 9,9-bis(t-butyl propionate) fluorene [9,9-bis {2-(t-butoxycarbonyl)ethyl}fluorene] (yield: 99%). The compound was further dissolved in 300 mL of isopropyl alcohol of 70° C. and then recrystallized by cooling to 10° C. to obtain 9,9-bis(2-methoxycarbonylethyl) fluorene.

Abbreviations in the description below each represent the following.

BPEF: 9,9-bis [4-(2-hydroxyethoxy)phenyl]fluorene, manufactured by Osaka Gas Chemicals Co., Ltd.

EG: ethylene glycol

DMN: dimethyl 2, 6-naphthalenedicarboxylate

PMMA: polymethyl methacrylate, PARAPET GR-01240, manufactured by Kuraray Co., Ltd.

Ultraviolet absorber: Adekastab LA-F70 [2, 4, 6-tris(2-hydroxy-4-hexyloxy-3-methylphenyl)-1, 3, 5-triazine], manufactured by ADEKA Corp.

### Synthesis Example 1: Ultraviolet-Curable Adhesive

70 parts by mass of urethane acrylate oligomer A1-1 (represented by the following general formula (9)) described in Examples of Japanese Patent Laid-Open No. 2018-087284, 30 parts by mass of phenoxyethyl acrylate (manufactured by Kyoeisha Chemical Co., Ltd.), and 5 parts by mass of a polymerization initiator (Irgacure 184, manufactured by BASF Japan Ltd.) were mixed to obtain a composition.

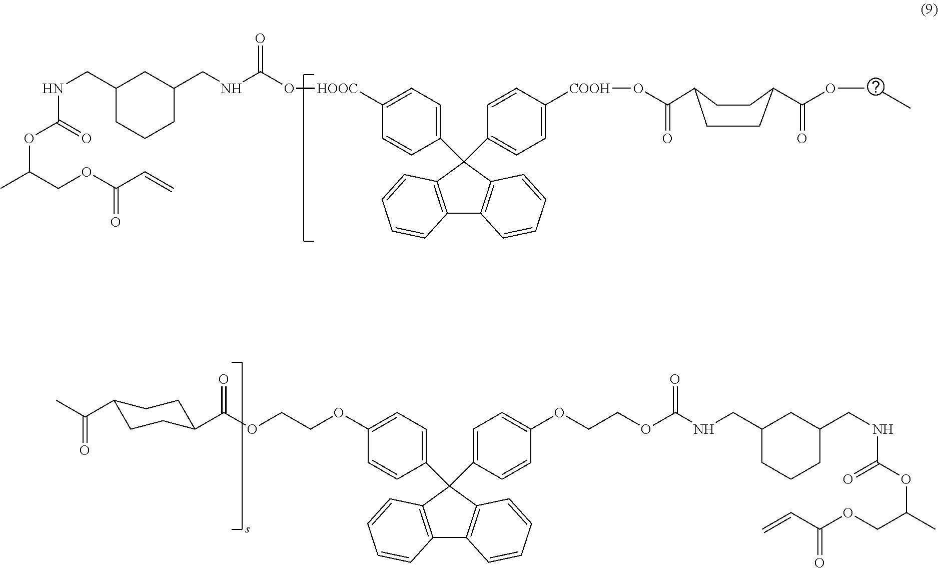

### [Preparation of Starting Material] (Polymerization for Fluorene-Based Polyester)

### Production Example 1

To 1.00 mol of FDPM, 0.80 mol of BPEF, and 2.20 mol of EG, 2×10⁻⁴ mol of manganese acetate tetrahydrate and 8×10⁻⁴ mol of calcium acetate monohydrate were added as a transesterification catalyst, and the mixture was gradually melted by heating with stirring. After temperature elevation to 230° C., 14×10⁻⁴ mol of trimethyl phosphate and 20×10⁻⁴ mol of germanium oxide were added thereto, and EG was removed by gradual temperature elevation and pressure reduction until reaching 270° C. and 0.13 kPa or lower. After reaching a predetermined stirring torque, the contents were isolated from the reactor to prepare fluorene-based polyester pellets (resin I).

As a result of analyzing the obtained pellets by ¹H-NMR, 100% by mol of dicarboxylic acid components introduced in the fluorene-based polyester was derived from FDPM, and 80% by mol and 20% by mol of diol components introduced therein were derived from BPEF and EG, respectively. The obtained fluorene-based polyester had glass transition temperature Tg of 126° C. and weight-average molecular weight Mw of 43600.

### Production Example 2

Polyester resin II in which a unit derived from each component was introduced at the ratio shown in Table 1 was obtained through the same reaction as in Production Example 1 except that the starting materials were changed to 0.70 mol of FDPM, 0.30 mol of DMN, 0.85 mol of BPEF, and 2.15 mol of EG.

As a result of analyzing the obtained pellets by NMR, 70% by mol and 30% by mol of dicarboxylic acid components introduced in the polyester resin were derived from FDPM and DMN, respectively, and 85% by mol and 15% by mol of diol components introduced therein were derived from BPEF and EG, respectively. The obtained fluorene-based polyester had glass transition temperature Tg of 132° C. and weight-average molecular weight Mw of 39900.

### (Addition of Ultraviolet Absorber)

A dry blend of 90 parts by mass of dried pellets of resin I and 10 parts by mass of an ultraviolet absorber was supplied as a starting material to a twin-screw extrusion apparatus (manufactured by Technovel Corp., model “KZW 15/45”, screw diameter D=15 mm, L/D=32) and kneaded at a screw temperature of 280° C. and a rotational speed of 200 rpm to prepare pellets (resin III).

Pellets (resin IV) were prepared by the addition of an ultraviolet absorber by the same method as above except that the starting material resin I was changed to resin II.

### Examples 1 to 10

### (Film Formation Step)

Resin I, III, or IV dried overnight in hot air at 80° C. and PMMA were coextrusion-molded as starting materials using a T die extrusion molding machine having three extruders to prepare a 2-resin 3-layer multilayer optical film having the layer configuration, the thickness ratios, and the total thickness shown in Table 1. The cylinder temperatures were set to 280 to 300° C. on the resin I, III, and IV side and 250° C. on the PMMA side. The thickness ratio of each layer was controlled by adjusting the number of screw rotations in each extruder.

### (Drawing Step)

Each multilayer film obtained in the film formation step was subjected to simultaneous biaxial drawing under the drawing conditions shown in Table 1 using a tenter drawing apparatus. In Table 1, the draw ratio shows the ratios of drawing in the longitudinal direction (machine direction) and the transverse direction (cross direction). Various physical properties of the obtained drawn film were measured. The results are shown in Table 1.

### Comparative Examples 1 and 2

Resin I was used, and a single-layer film of fluorene-based polyester resin I was formed using a T die extrusion molding machine and drawn in the same manner as in Examples described above. Various physical properties of the obtained drawn film were measured. The results are shown in Table 1.

### Comparative Example 3

Various physical properties of acrylic resin film “PARAPURE HI-50” (thickness: 75 μm) manufactured by Kuraray Co, Ltd. were measured. The results are shown in Table 1.

TABLE 1

| | | | | | | | Characteristics | | | | |
|---|---|---|---|---|---|---|---|---|---|---|---|
| | Film formation step | | | Drawing step | | | R₀ | Rₜₕ | | Peel | Spectral |
| | | | Total | Temper- | | Total | (550 | (589 | | strength | transmittance |
| | Layer | Thickness | thickness | ature | | thickness | nm) | nm) | Flex | against | (380 nm) |
| | configuration | ratio | [μm] | [° C.] | Ratio | [μm] | [nm] | [nm] | resistance | PVA | [%] |
| Example 1 | PMMA/I/PMMA | 45%/10%/45% | 155 | 134 | 2 × 2 | 47 | 2 | −30 | ⊚ | ◯ | 88.3 |
| Example 2 | PMMA/III/PMMA | 45%/10%/45% | 155 | 134 | 2 × 2 | 46 | 2 | −27 | ⊚ | ◯ | 0.6 |
| Example 3 | PMMA/III/PMMA | 45%/10%/45% | 156 | 139 | 2 × 2 | 46 | 1 | −20 | ⊚ | ◯ | 0.6 |
| Example 4 | PMMA/III/PMMA | 68%/9%/23% | 142 | 139 | 1.5 × 1.5 | 81 | 2 | −21 | ◯ | ◯ | 0.1 |
| Example 5 | PMMA/III/PMMA | 68%/9%/23% | 140 | 139 | 1.8 × 1.8 | 50 | 1 | −19 | ⊚ | ◯ | 0.6 |
| Example 6 | PMMA/III/PMMA | 68%/9%/23% | 127 | 139 | 1.5 × 1.5 | 70 | 1 | −19 | ◯ | ◯ | 0.1 |
| Example 7 | PMMA/III/PMMA | 68%/9%/23% | 124 | 139 | 1.8 × 1.8 | 52 | 2 | −17 | ⊚ | ◯ | 1.3 |
| Example 8 | PMMA/III/PMMA | 68%/9%/23% | 133 | 139 | 2 × 2 | 36 | 0 | −12 | ⊚ | ◯ | 1.5 |
| Example 9 | PMMA/III/PMMA | 68%/9%/23% | 132 | 144 | 2.5 × 2.5 | 26 | 0 | −9 | ⊚ | ◯ | 6.8 |
| Example 10 | PMMA/IV/PMMA | 45%/10%/45% | 144 | 142 | 2 × 2 | 40 | 0 | 2 | ⊚ | ◯ | 1.0 |
| Comparative | I | Single layer | 110 | 139 | 1.5 × 1.5 | 58 | 5 | −116 | ⊚ | ◯ | 86.5 |
| Example 1 | | | | | | | | | | | |
| Comparative | I | Single layer | 111 | 139 | 2 × 2 | 34 | 12 | −106 | ⊚ | ◯ | 86.4 |
| Example 2 | | | | | | | | | | | |
| Comparative | HI-50 | Single layer | 75 | Undrawn | | | 3 | −8 | X | ◯ | 0.9 |
| Example 3 | | | | | | | | | | | |

As is evident from Table 1, a laminated film of a fluorene-based polyester resin and an acrylic resin such as PMMA was shown to produce a thin polarizer protective film that had a very low in-plane phase difference and phase difference in a thickness direction and is also excellent in flex resistance.

### INDUSTRIAL APPLICABILITY

The polarizer protective film of the present invention can satisfy required characteristics (low birefringence, high ultraviolet absorption performance, low moisture permeability, high mechanical characteristics, a small film thickness, etc.) for the polarizer protective film in a balanced fashion. Furthermore, the polarizer protective film of the present invention not only has high moldability and can be easily prepared as a thin film, but is largely advantageous in terms of cost because the polarizer protective film can be produced at a large scale by melt extrusion film formation using inexpensive materials. Hence, the polarizer protective film is very useful as a polarizing plate comprising this polarizer protective film and a polarizer. The polarizing plate can be used in a display (image display apparatus) of equipment, specifically, for example, an FPD apparatus (e.g., LCD, PDP, or OLED) for personal computer monitors, televisions, mobile phones (smartphones, etc.), tablet terminals, car navigations, touch panels, and the like.

### REFERENCE SIGNS LIST

10 . . . polarizer protective film, 11 . . . polyester-based resin layer, 12 . . . another layer, 20 and 30 . . . polarizing plate, 22, 24, 32, 33, and 35 . . . adhesive layer, 23 and 34 . . . polarizer, 21 and 31 . . . phase difference film, 40 . . . organic EL display apparatus, 41 . . . organic EL display panel, 42 . . . touch sensor, 43 . . . front panel, 50 . . . liquid crystal display apparatus, 51 . . . light source, 52 . . . liquid crystal panel, 53 . . . front panel, 60 . . . information processing apparatus, 61 . . . image display apparatus, 62 . . . image display apparatus housing.

1. A polarizer protective film which is a multilayer film having a polyester-based resin layer comprising a fluorene-based polyester resin, and acrylic resin layer comprising an acrylic resin, and
being formed by drawing, wherein
a thickness ratio of the polyester-based resin layer to the whole is 1 to 30%,
phase difference Rth(589) in a thickness direction at a wavelength of 589 nm is −50 nm or more and 50 nm or less, and
in-plane phase difference Ro(550) at a wavelength of 550 nm is 0 nm or more and 50 nm or less.

2. The polarizer protective film according to claim 1, wherein
the fluorene-based polyester resin is a co-polyester resin comprising repeat units represented by the following general formula (1) and the following general formula (3): 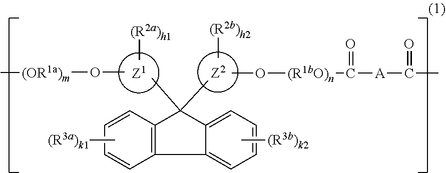
wherein A represents a benzene residue, a naphthaline residue, a cyclohexane residue, a decalin residue, or a fluorene residue represented by the following general formula (2), Z¹ and Z² are the same or different and each represent a phenylene group or a naphthylene group, R^{1a} and R^{1b} are the same or different and each represent a C₂₋₆ alkylene group, m and n are the same or different and each represent an integer of 1 to 5, R^{2a} and R^{2b} are the same or different and each represent an alkyl group, an alkoxy group, an aryl group, a cycloalkyl group, an aralkyl group, a cycloalkyloxy group, an aryloxy group, an alkylthio group, a dialkylamino group, a halogen atom, a nitro group, or a cyano group, h1 and h2 are the same or different and each represent an integer of 0 to 2, R^{3a} and R^{3b} are the same or different and each represent a substituent inert to reaction, and k1 and k2 are the same or different and each represent an integer of 0 to 4: 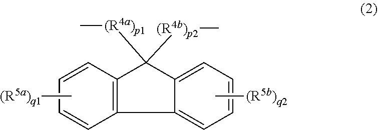
wherein R^{4a} and R^{4b} are the same or different and each represent a C₁₋₈ alkylene group, p1 and p2 are the same or different and each represent an integer of 1 to 5, R^{5a} and R^{5b} are the same or different and each represent a substituent inert to reaction, and q1 and q2 each represent an integer of 0 to 4, 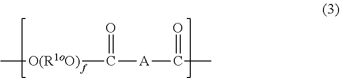
wherein A represents a benzene residue, a naphthaline residue, a cyclohexane residue, a decalin residue, or a fluorene residue represented by the general formula (2), R^{1c} represents a C₂₋₄ alkylene group, and r represents an integer of 1 to 3.

3. The polarizer protective film according to claim 1, wherein
the polyester-based resin layer comprising the fluorene-based polyester resin is a polymer alloy comprising the fluorene-based polyester resin and a polycarbonate resin.

4. The polarizer protective film according to claim 1, wherein
the acrylic resin comprises a repeat unit represented by any of the following general formulas (4), (5), and (6): 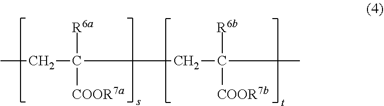
wherein R^{6a} and R^{6b} are the same or different and each represent a hydrogen atom or a C₁₋₈ alkyl group, R^{7a} and R^{7b} are the same or different and each represent a hydrogen atom, a C₁₋₁₈ alkyl group, a C₃₋₁₂ cycloalkyl group, or a substituent containing a C₅₋₁₅ aromatic ring, and s and t each represent a molar fraction with s+t=1, 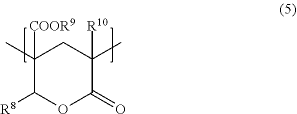
wherein R⁸ represents a hydrogen atom or an organic residue having 1 to 20 carbon atoms, wherein the organic residue optionally contains an oxygen atom, R⁹ represents a hydrogen atom, a C₁₋₁₈ alkyl group, a C₃₋₁₂ cycloalkyl group, or a substituent containing a C₅₋₁₅ aromatic ring, and R¹⁰ represents a hydrogen atom or a C₁₋₈ alkyl group, 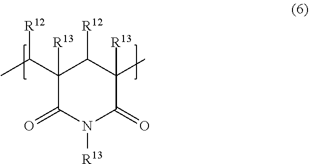
wherein R¹¹ and R¹² are the same or different and each represent a hydrogen atom or a C₁₋₈ alkyl group, and R¹³ represents a hydrogen atom, a C₁₋₁₈ alkyl group, a C₃₋₁₂ cycloalkyl group, or a substituent containing a C₅₋₁₅ aromatic ring.

5. The polarizer protective film according to claim 1, wherein
the acrylic resin comprises polymethyl methacrylate.

6. The polarizer protective film according to claim 1, wherein
the acrylic resin layer comprising the acrylic resin is a polymer alloy comprising the acrylic resin and a polyester resin or a polycarbonate resin.

7. The polarizer protective film according to claim 6, wherein
the polyester resin or the polycarbonate resin contained in the acrylic resin layer is a fluorene-based polyester resin or a fluorene-based polycarbonate resin.

8. The polarizer protective film according to claim 1, wherein
the polyester-based resin layer and the acrylic resin layer are configured in contact without a layer intended for adhesion.

9. The polarizer protective film according to claim 1, wherein
an outermost layer of the multilayer film is the acrylic resin layer, and the multilayer film has three or more layers.

10. The polarizer protective film according to claim 1, wherein
the polyester-based resin layer contains an ultraviolet absorber.

11. The polarizer protective film according to claim 1, wherein
the multilayer film has a spectral transmittance of 10% or less at 380 nm and a total light transmittance of 85% or more.

12. The polarizer protective film according to claim 1, wherein
the polarizer protective film has a surface treatment layer on the surface.

13. The polarizer protective film according to claim 1, wherein
the surface treatment layer has any one or more of hard coat, antiglare, antireflection, low-reflection, antifouling, and anti-fingerprint effects.

14. A polarizing plate wherein
the polarizer protective film according to claim 1 and a polarizer formed from a polyvinyl alcohol-based resin are laminated through an ultraviolet-curable adhesive.

15. The polarizing plate according to claim 14, wherein
the ultraviolet-curable adhesive is a composition containing a reaction product of polyester polyol having a 9,9-bis(aryl)fluorene skeleton, a diisocyanate compound, and a hydroxy group-containing acrylate compound, and a monofunctional acrylate compound.

16. An image display apparatus comprising
the polarizing plate according to claim 14.

17. An image display apparatus comprising
the polarizing plate according to claim 14 and a touch sensor.

18. The image display apparatus according to claim 17, wherein
the touch sensor has an on-cell system or an in-cell system.

19. The image display apparatus according to claim 17, wherein
the touch sensor is a capacitive touch sensor having at least one conductive film.

20. The image display apparatus according to claim 19, wherein
a base material of the conductive film is a polyester resin, a cycloolefin resin, a polycarbonate resin, or a polyimide resin.

21. The image display apparatus according to claim 19, wherein
the conductive film comprises a plurality of metal thin wires.

22. The image display apparatus according to claim 21, wherein
the metal thin wires are made of silver, copper, or an alloy comprising at least one of silver and copper.

23. The image display apparatus according to claim 20, wherein
the conductive film comprises at least one of indium tin oxide (ITO), antimony-doped tin oxide (ATO), a conductive polymer, and a carbon-based material.

24. The image display apparatus according to claim 16, wherein
the image display apparatus has a changeable shape.

25. The image display apparatus according to claim 16, wherein
the image display apparatus is an in-car image display apparatus.

26. An information processing apparatus comprising
the image display apparatus according to claim 16.
